(19) United States
(12) Patent Application Publication
(10) Pub. No.: US 2026/0190635 A1
(43) Pub. Date: Jul. 2, 2026

(54) Display Device

(71) Applicant: LG Display Co., Ltd., Seoul (KR)

(72) Inventors: Wonrae Kim, Paju-si (KR); KyungKook Jang, Paju-si (KR)

(21) Appl. No.: 19/265,411

(22) Filed: Jul. 10, 2025

(30) Foreign Application Priority Data
Dec. 31, 2024 (KR) 10-2024-0202214

(51) Int. Cl. H10K 59/122; H10H 29/32; H10H 29/34; H10H 29/37; H10H 29/854; H10K 59/121; H10K 59/35; H10K 59/80

(52) U.S. Cl. CPC H10K 59/122; H10H 29/32; H10H 29/345; H10H 29/37; H10H 29/854; H10K 59/1213; H10K 59/352; H10K 59/873

(57) ABSTRACT

Provided are a display device and a display panel. The display device comprises a display panel including a display area displaying images and including a plurality of subpixels, each of the plurality of subpixels including a light emitting area; and a bank disposed around the light emitting area, wherein the bank includes two or more openings partially overlapping with each other in a direction perpendicular to the display panel, and wherein the two or more openings have different shapes.

### CROSS REFERENCE TO RELATED APPLICATION

This application claims priority from Republic of Korea Patent Application No. 10-2024-0202214, filed on Dec. 31, 2024, which is hereby incorporated by reference in its entirety.

### TECHNICAL FIELD

The present disclosure relates to electronic devices, and more specifically, to display devices and a display panel that include a structure where an opening of a first bank and an opening of a second bank have different shapes, and thereby, are capable of improving reflective visibility.

### DISCUSSION OF RELATED ART

Display devices are widely used not only as televisions or monitors, but as display screens for notebook computers, tablet computers, smart phones, portable display devices, portable information devices, and the like.

As display technology advances, various types or usages of display devices have been developed. Among these display devices, organic light emitting display devices using self-emissive organic light emitting diodes (OLED) exhibit high response speed and have advantages in contrast ratio, emission efficiency, luminance, viewing angle, and the like, compared with other types of display devices such as a liquid crystal display (LCD) device and the like.

These organic light emitting display devices may have a structure where a corresponding one of a plurality of organic light emitting diodes is disposed in each of a plurality of subpixels disposed in a display panel, and thereby, can display images by light emitted from each subpixel through driving current flowing to each organic light emitting diode controlled by a corresponding driving transistor.

In this configuration, an encapsulation layer may be disposed in an upper portion of the display panel to prevent external moisture or oxygen from penetrating into light emitting elements.

The description provided in the description of the related art section should not be assumed to be prior art merely because it is mentioned in or associated with the description of the related art section. The description of the related art section may include information that describes one or more aspects of the subject technology, and the description in this section does not limit the disclosure.

### SUMMARY

The inventor has realized that in the related art, as the display panel tends to become thinner, a thickness of the encapsulation layer is also becoming thinner, and as a result, there often occurs a situation where the encapsulation layer is not properly formed on light emitting elements. Accordingly, to address this issue, one or more aspects of the present disclosure may provide a display device that includes a structure where an opening of a first bank and an opening of a second bank have different shapes, and thereby, is capable of improving reflective visibility.

One or more aspects of the present disclosure may provide a display device that includes a structure where an opening of a first bank and an opening of a second bank have different shapes, and is capable of improving the flowability of a material included in an encapsulation layer.

One or more aspects of the present disclosure may provide a display device that includes a structure where an opening of a first bank and an opening of a second bank have different shapes, and is capable of causing a material included in an encapsulation layer to be easily spread into an open area.

A display device according to one example embodiment of the present disclosure comprises a display panel including a display area displaying images and including a plurality of subpixels, each of the plurality of subpixels including a light emitting area; and a bank disposed around the light emitting area, wherein the bank includes two or more openings partially overlapping with each other in a direction perpendicular to the display panel, and wherein the two or more openings have different shapes.

A display panel according to one example embodiment of the present disclosure comprises a substrate including a display area displaying images and including a plurality of subpixels, each of the plurality of subpixels including a light emitting area; and a bank disposed around the light emitting area, wherein the bank includes two or more openings partially overlapping with each other in a direction perpendicular to the display panel, and wherein the two or more openings have different shapes.

Aspects, examples, and embodiments provided in the present disclosure are not limited to the foregoing description, and additional aspects, examples, and embodiments provided in the present disclosure will become apparent to those skilled in the art from the following description.

According to one or more aspects of the present disclosure, a display device may be provided that is capable of improving reflective visibility by including a structure where an opening of a first bank and an opening of a second bank have different shapes.

According to one or more aspects of the present disclosure, a display device may be provided that is capable of improving the flowability of a material included in an encapsulation layer by including a structure where an opening of a first bank and an opening of a second bank have different shapes.

According to one or more aspects of the present disclosure, a display device may be provided that is capable of causing a material included in an encapsulation layer to be easily spread into an open area by including a structure where an opening of a first bank and an opening of a second bank have different shapes.

According to one or more aspects of the present disclosure, a display device may be provided that is capable of enabling process optimization through the application of an inkjet process for forming an encapsulation layer by including a structure where an opening of a first bank and an opening of a second bank have different shapes.

Effects or advantages from aspects, examples, and embodiments described herein are not limited thereto, and additional effects or advantages will become apparent to those skilled in the art from the following description.

### BRIEF DESCRIPTION OF THE DRAWINGS

The accompanying drawings, which are included to provide a further understanding of the disclosure and are incorporated in and constitute a portion of the disclosure, illustrate aspects of the disclosure and together with the description serve to explain principles of the disclosure. It should be therefore understood that aspects, examples, and embodiments described herein are not limited to the illustrations of the accompanying drawings. In the drawings:

FIG. 1 illustrates an example system configuration of a display device according to embodiments of the present disclosure;

FIG. 2 is an example plan view of the display panel according to embodiments of the present disclosure;

FIG. 3 is an example cross-sectional view taken along line I-I′ of FIG. 2 in the display panel according to embodiments of the present disclosure;

FIG. 4 is an example plan view of an area of the display panel according to embodiments of the present disclosure;

FIG. 5 is another example plan view of an area of the display panel according to embodiments of the present disclosure;

FIG. 6 is an example enlarged plan view of an opening of a bank in the display panel according to embodiments of the present disclosure;

FIG. 7 is an example enlarged plan view of area X in FIG. 6;

FIGS. 8A, 8B, and 8C are example cross-sectional views taken along lines A-B, C-D, and E-F of FIG. 5 in the display panel according to embodiments of the present disclosure;

FIG. 9 illustrates example reflection paths of external light in the bank of the display panel according to embodiments of the present disclosure;

FIG. 10, FIG. 11 and FIG. 12 illustrate example reflection paths of external light in the bank of the display panel according to embodiments of the present disclosure;

FIG. 13 is an example cross-sectional view taken along line G-H of FIG. 5 in the display panel according to embodiments of the present disclosure;

FIG. 14 illustrates an example process of forming an encapsulation layer in the display panel according to embodiments of the present disclosure;

FIG. 15 is an example cross-sectional view taken along line II-II′ of FIG. 2 in an outer area of the display panel according to embodiments of the present disclosure;

FIG. 16 is an example cross-sectional view taken along line III-III′ of FIG. 2 in an outer area of the display panel according to embodiments of the present disclosure; and

FIG. 17, FIG. 18, FIG. 19, FIG. 20, FIG. 21, FIG. 22, FIG. 23, FIG. 24, FIGS. 25 and 26 illustrate example shapes of openings of the bank in the display panel according to embodiments of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to example embodiments of the present disclosure, examples or aspects of which may be illustrated in the accompanying drawings. In the following description, the structures, implementations, methods, and operations described herein are not limited to the specific examples, aspects, and embodiments set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure.

Further, the protected scope of the present disclosure is defined by claims and their equivalents. In the following description, where the detailed description of the relevant known function or configuration may unnecessarily obscure aspects of the present disclosure, a detailed description of such known function or configuration may be omitted.

The shapes, sizes, dimensions (e.g., length, width, height, thickness, radius, diameter, area, etc.), ratios, angles, numbers, and the like, which are illustrated in the drawings to describe various example embodiments of the present disclosure, are merely given by way of example. Therefore, the present disclosure is not limited to the illustrations in the drawings.

The terms such as “include,” “have,” “comprise,” “contain,” “constitute,” “make up of,” “formed of,” and “consist of” used herein are generally intended to allow other components to be added unless the terms are used with the term “only”.

As used herein, singular forms are intended to include plural forms unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts”, “overlaps with”, or the like a second element, it should be interpreted that, not only can the first element “be directly connected or coupled to”, “directly contact”, or “directly overlap with” the second element, but a third element can also be “interposed” between the first and second elements, or the first and second elements can “be connected or coupled to”, “contact”, “overlap with”, or the like each other via a fourth element. Here, the second element may be included in at least one of two or more elements that “are connected or coupled to”, “contact”, “overlap with”, or the like each other.

Where positional relationships are described, for example, where the positional relationship between two parts is described using “on”, “above”, “over”, “below”, “under”, “beside”, “beneath”, “near”, “close to,” “adjacent to”, “on a side of”, “next” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the example term “below” can encompass both an orientation of below and above. Similarly, the example term “above” or “over” can encompass both an orientation of “above” and “below”.

In a description of a temporal relationship, when the temporal relationship is described as “after,” “following,” “and then,” “before,” or the like, non-consecutive cases may also be included unless “immediately” or “directly” is used.

In addition, when any dimensions, relative sizes etc. are mentioned, it should be considered that numerical values for an elements or features, or corresponding information (e.g., level, range, and the like) include a tolerance or error range that may be caused by various factors (e.g., process factors, internal or external impact, noise, and the like) even when a relevant description is not specified. Further, the term “may” fully encompasses all the meanings of the term “can”.

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

“At least one” should be understood as including a combination of one or more of the related components. For example, the term “at least one of first, second, and third components” includes not only the first, second, or third component, but also all combinations of two or more of the first, second, and third components.

The terms “first direction,” “second direction,” “third direction,” “X-axis direction,” “Y-axis direction,” and “Z-axis direction” should not be understood as only a geometric relationship in which a relationships therebetween are perpendicular to each other, but mean that a configuration of the present disclosure has a broader directionality within a range in which it may functionally act.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

Features of various example embodiments of the present disclosure may be partially or entirely combined with each other, and technically, various linkages and operations are possible, and the example embodiments may be implemented independently of each other or together in a related relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

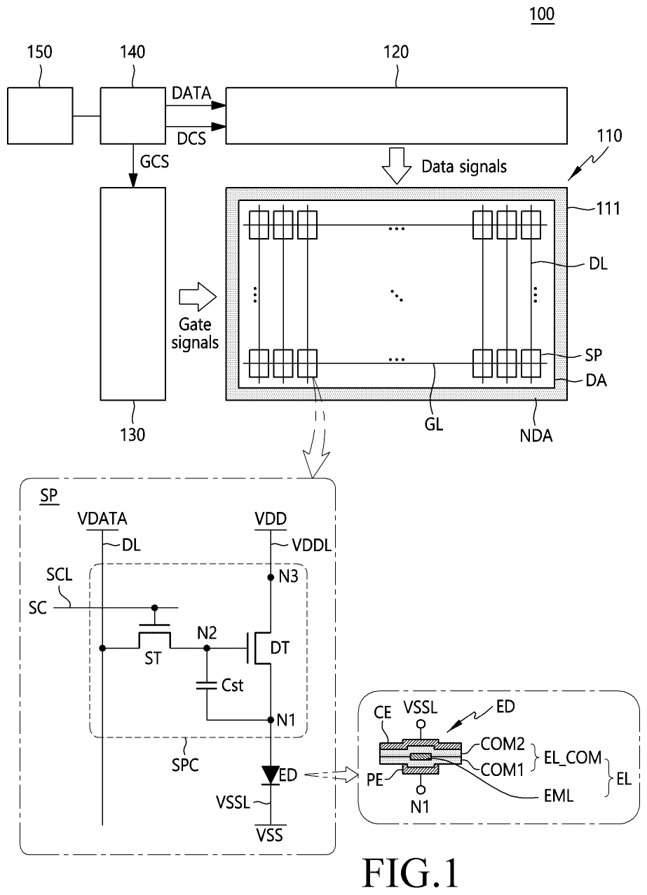

FIG. 1 illustrates an example system configuration of a display device 100 according to embodiments of the present disclosure. All components of each display device according to all embodiments of the present disclosure are operatively coupled and configured.

Referring to FIG. 1, in one or more example embodiments, the display device 100 may include a display panel 110 and at least one display driving circuit, as elements for display images. The at least one display driving circuit may be a circuit for driving the display panel 110, and include a data driving circuit 120, a gate driving circuit 130, a controller 140, and other circuit components. Lines through which control signals for controlling the driving circuits are supplied may be disposed on the display panel. For example, the control signals may include various timing signals including a clock signal, an input data enable signal, and a synchronization signal (for example, a horizontal synchronization signal and a vertical synchronization signal), but the example embodiments of the present disclosure are not limited thereto. Here, the horizontal synchronization signal is a signal representing a time taken to display one horizontal line of a screen and the vertical synchronization signal is a signal representing a time taken to display a screen of one frame. The input data enable signal may correspond to a signal indicating a period for which a data voltage is supplied to the pixel.

The display panel 110 may include a substrate 111 and a plurality of subpixels SP disposed on the substrate 111.

The substrate 111 may include a display area DA allowing an image to be displayed and a non-display area NDA located outside of the display area DA. The display area DA and the non-display area NDA may be referred to as areas of the display panel 110.

The display area DA may also be referred to as an active area, and a plurality of subpixels SP for displaying images may be disposed in the display area DA. Each of the plurality of subpixels is a minimum unit which configures the display area and n subpixels form one pixel. Each of the plurality of subpixels may emit light having different wavelengths from each other. The plurality of subpixels may include first to third subpixels which emit different color light from each other. For example, the sub-pixels may include red, green, and blue sub-pixels. Meanwhile, the sub-pixels may also include white sub-pixel. The plurality of subpixels may be variously modified in colors and configurations, as necessary. However, the present disclosure is not limited thereto.

For example, the plurality of subpixels may include red, green, and blue subpixels, in which the red, green, and blue subpixels may be disposed in a repeated manner. Alternatively, the plurality of subpixels may include red, green, blue, and white subpixels, in which the red, green, blue, and white subpixels may be disposed in a repeated manner, or the red, green, blue, and white subpixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the subpixels are not limiting, and may be configured in various forms according to light-emitting characteristics, device lifespans, and device specifications.

Meanwhile, the subpixels may have different light-emitting areas according to light-emitting characteristics. For example, a subpixel that emits light of a color different from that of a blue subpixel may have a different light-emitting area from that of the blue subpixel. For example, the red subpixel, the blue subpixel, and the green subpixel, or the red subpixel, the blue subpixel, the white subpixel, and the green subpixel may each has a different light-emitting area.

A plurality of light-emitting elements may be disposed in each of the plurality of subpixels. The plurality of light-emitting elements may be configured differently depending on the type of display device. For example, when the display device is an inorganic light-emitting display device, the light-emitting element may be an inorganic light-emitting diode (LED), a micro light-emitting diode (micro LED), or a mini light-emitting diode (mini LED), but the example embodiments of the present disclosure are not limited thereto.

The non-display area NDA may be a region where an image is not displayed. The non-display area NDA may be placed outside the display area DA. For example, the non-display area NDA may be an area adjacent to the display area DA. Further, the non-display area NDA may be an area disposed adjacent to the display area DA and configured to surround the display area DA. Various lines and circuits for driving the plurality of pixels of the display area DA may be disposed in the non-display area NDA. The non-display area NDA may also be referred to as a non-active area and include a pad area. For example, in the non-display area NDA, various lines and driving circuits may be mounted, and a pad portion to which an integrated circuit, a printed circuit, and the like are connected may be disposed, but the example embodiments of the present disclosure are not limited thereto.

In one or more embodiments, the display panel 110 may be configured to have a very small non-display area NDA. The non-display area NDA may be also referred to as a “bezel” or an “bezel area.” For example, the non-display area NDA may include a first non-display area located outside of the display area DA in a first direction, a second non-display area located outside of the display area DA in a second direction, a third non-display area located outside of the display area DA in a direction opposite to the first direction, and a fourth non-display area located outside of the display area DA in a direction opposite to the second direction.

The first non-display area among the first to fourth non-display areas may include a pad area to which one or more driving circuits are connected or bonded. Among the first to fourth non-display areas, the second to fourth non-display areas may have a very small size compared to the first non-display area.

In another example, a boundary area may be defined between the display area DA and the non-display area NDA. In this example, the boundary area may be bent at a certain angle to the display area DA, and thereby, the non-display area NDA may be located under the display area DA. In this implementation, when a user views the display device 100 in front thereof, all or most of the non-display area NDA may be invisible to the user. For example, the first non-display area may include a bending area. As the bending area is bent, the first non-display area may be invisible in front of the display device 100.

Several types of signal lines for driving a plurality of subpixels SP may be disposed on the substrate 111 of the display panel 110.

In one or more embodiments, the display device 100 may be a liquid crystal display device, or the like, or a self-emissive display device in which light is emitted from the display panel 110 itself. In an example where the display device 100 is the self-emissive display device, each of the plurality of subpixels SP may include a light emitting element.

For example, the display device 100 according to embodiments of the present disclosure may be an organic light emitting display device in which light emitting elements are implemented using organic light emitting diodes (OLED). In another example, the display device 100 according to embodiments of the present disclosure may be an inorganic light emitting display device in which light emitting elements are implemented using inorganic material-based light emitting diodes. In further another example, the display device 100 according to embodiments of the present disclosure may be a quantum dot display device in which light emitting elements are implemented using quantum dots, which are self-emission semiconductor crystals.

The structure of each of the plurality of subpixels SP may depend on types of display device 100. For example, in an example where the display device 100 is a self-emissive display device including self-emissive subpixels SP, each subpixel SP may include a self-emissive light emitting element, one or more transistors, and one or more capacitors.

Each of one or more transistors may be implemented as a thin film transistor (TFT).

Active layers of the thin-film transistors TFTs may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

Referring to FIG. 1, each or at least one of the plurality of subpixels SP disposed in the display panel 110 may include a light emitting element ED and a subpixel circuit SPC configured to drive the light emitting element ED.

Referring to FIG. 1, the subpixel circuit SPC may include a plurality of transistors and at least one capacitor for driving the light emitting element ED. The subpixel circuit SPC can drive the light emitting element ED by supplying a driving current to the light emitting element ED at a predetermined timing. The light emitting element ED can emit light by being driven by the driving current.

The plurality of transistors may include a driving transistor DT for driving the light emitting element ED and a scan transistor ST configured to be turned on or off according to a scan signal SC.

The driving transistor DT can supply a driving current to the light emitting element ED.

The scan transistor ST may be configured to control an electrical state of a corresponding node in the subpixel circuit SPC or to control the state or operation of the driving transistor DT.

The at least one capacitor may include a storage capacitor Cst configured to maintain a voltage at a constant level during a display frame or a period of the display frame.

To drive at least one subpixel SP, at least one data signal VDATA, which is an image signal, and at least one scan signal SC, which is a gate signal, may be applied to the at least one subpixel SP. Further, to drive at least one subpixel SP, at least one common voltage including a first common voltage VDD and a second common voltage VSS may be applied to the at least one subpixel SP.

The light emitting element ED may include a pixel electrode PE, an intermediate layer EL, and a common electrode CE. The intermediate layer EL may be disposed between the pixel electrode PE and the common electrode CE. The first electrode PE may be a pixel electrode PE, and the second electrode CE may be a common electrode CE.

For example, the pixel electrode PE may be an electrode disposed for each subpixel SP, and the common electrode CE may be an electrode disposed commonly in all or some of a plurality of subpixels SP. For example, the pixel electrode PE may be an anode electrode, and the common electrode CE may be a cathode electrode. In another example, the pixel electrode PE may be a cathode electrode, and the common electrode CE may be an anode electrode. Hereinafter, for convenience of explanation, discussions may be provided based on examples where the pixel electrode PE is an anode electrode, and the common electrode CE is a cathode electrode.

In an example where the light emitting element ED is an organic light emitting diode, the intermediate layer EL may include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 may be referred to as a common intermediate layer EL_COM.

In one or more embodiments, the emission layer EML may be disposed for each subpixel SP, and the common intermediate layer EL_COM may be commonly disposed across all or some of a plurality of subpixels SP.

For example, the emission layer EML may be disposed for each light emitting area, and the common intermediate layer EL_COM may be commonly disposed across a plurality of light emitting areas and a non-light emitting area.

In one or more embodiments, the emission layer EML and the common intermediate layer EL_COM may be commonly disposed across all or some of a plurality of subpixels SP.

For example, the emission layer EML and the common intermediate layer EL_COM may be commonly disposed across a plurality of light emitting areas and a non-light emitting area.

For example, the first common intermediate layer COM1 may include a hole injection layer (HIL), a hole transfer layer (HTL), and the like. The second common intermediate layer COM2 may include an electron transport layer (ETL), an electron injection layer (EIL), and the like, but not limited thereto.

The hole injection layer can inject holes from the pixel electrode PE to the hole transport layer, the hole transport layer can transport holes to the emission layer EML. The electron injection layer can inject electrons from the common electrode CE to the electron transport layer, and the electron transport layer can transport electrons to the emission layer EML.

In one or more embodiments, the common electrode CE may be electrically connected to a second common voltage line VSSL. A second common voltage VSS may be applied to the common electrode CE through the second common voltage line VSSL. The pixel electrode PE may be electrically connected directly or indirectly (via another transistor) to a first node N1 of a corresponding driving transistor DT of each subpixel SP.

Herein, a first common voltage VDD may also be referred to as a “high voltage” or a “driving voltage”, and a first common voltage line VDDL may also be referred to as a “high voltage line”, or a “driving voltage line”. Herein, the second common voltage VSS may also be referred to as a “low voltage” or a “base voltage”, and the second common voltage line VSSL may also be referred to as a “low voltage line” or a “base voltage line.

Each light emitting element ED may be configured by overlapping of a pixel electrode PE, an emission layer EML in an intermediate layer EL, and a common electrode CE. A respective light emitting area may be formed by each light emitting element ED. For example, a respective light emitting area of each light emitting element ED may include an area where a pixel electrode PE, an emission layer EML in an intermediate layer EL, and a common electrode CE overlap with each other.

In one or more embodiments, the light emitting element ED may be an organic light emitting diode (OLED), an inorganic light emitting diode (LED), a quantum dot light emitting element, or the like. In the example where each light emitting element ED is an organic light emitting diode (OLED), the intermediate layer EL of a corresponding light emitting element ED may be a layer including an organic material.

The driving transistor DT may be a transistor configured to supply a driving current to the light emitting element ED. The driving transistor DT may be connected between a first common voltage line VDDL and the light emitting element ED.

The driving transistor DT may include a first node N1, a second node N2, and a third node N3. The first node N1 may be electrically connected to the light emitting element ED. A data signal VDATA may be applied to the second node N2. A first common voltage VDD delivered through the first common voltage line VDDL may be applied to the third node N3.

In the driving transistor DT, the second node N2 may be a gate node, the first node N1 may be a source node or a drain node, and the third node N3 may be the drain node or the source node. Hereinafter, for merely convenience of explanation, discussions may be provided based on examples where the second node N2 is a gate node, the first node N1 is a source node or a drain node, and the third node N3 id the drain node or the source node. However, embodiments of the present disclosure are not limited thereto.

The scan transistor ST included in the subpixel circuit SPC illustrated in FIG. 1 may be a switching transistor for transferring a data signal VDATA, which is an image signal, to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST may be electrically connected to the data line DL. The source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the second node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed to be located outside of the driving transistor DT, and therefore, be different from an internal capacitor such as a parasitic capacitor (e.g., a Cgs, a Cgd) that may be formed between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

In an example where the display panel 110 has the top emission structure, at least a portion of the subpixel circuit SPC may overlap with at least a portion of the light emitting element ED in the vertical direction. In this configuration, the area or size of a corresponding light emitting area can increase, and a corresponding aperture ratio can increase.

In an example where the display panel 110 has the bottom emission structure, the subpixel circuit SPC may not overlap with the light emitting element ED in the vertical direction.

As shown in FIG. 1, the subpixel circuit SPC may include two transistors (2T: DT and ST) and one capacitor (1C: Cst) (which may be referred to as a “2T1C structure”), and in some implementations, may further include one or more transistors, or further include one or more capacitors.

For example, the subpixel circuit SPC may have an 8T1C structure including 8 transistors and 1 capacitor. In another example, the subpixel circuit SPC may have an 6T2C structure including 6 transistors and 2 capacitor. In another example, the subpixel circuit SPC may have an 7T1C structure including 7 transistors and 1 capacitor. However, embodiments of the present disclosure are not limited to such specific structures.

The types and number of signals supplied to a subpixel SP, and/or the types and number of lines connected to the subpixel SP may vary depending on a structure of a corresponding subpixel circuit SPC. Further, the types and number of common driving voltages supplied to a subpixel SP may vary depending on a structure of a corresponding subpixel circuit SPC.

The several types of signal lines may include, for example, a plurality of data lines DL for carrying data signals (which may be referred to as data voltages or image signals), a plurality of gate lines GL for carrying gate signals (which may be referred to as scan signals), and the like.

In one or more embodiments, the plurality of data lines DL and the plurality of gate lines GL may intersect one another. Each of the plurality of data lines DL may be configured to extend in a first direction, and each of the plurality of gate lines GL may be configured to extend in a second direction. For example, the first direction may be the column direction, and the second direction may be the row direction. In another example, the first direction may be the row direction, and the second direction may be the column direction. Hereinafter, for merely convenience of explanation, discussions are provided based on examples where the first direction is the column direction and the second direction is the row direction. Hereinafter, for convenience of explanation, discussions may be provided based on examples where each of a plurality of data lines DL is disposed in the column direction, and each of a plurality of gate lines GL is disposed in the row direction, but embodiments of the present disclosure are limited thereto.

The data driving circuit 120 may be a circuit for driving a plurality of data lines DL and can output data signals to the plurality of data lines DL.

The data driving circuit 120 can receive image data DATA in a digital form from the controller 140, and convert the received image data DATA into data signals in an analog form, and output the converted data signals to the plurality of data lines DL.

In some embodiments, the data driving circuit 120 may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique. However, embodiments of the present disclosure are not limited thereto.

In one or more embodiments, the data driving circuit 120 may be disposed in, and/or electrically connected to, but not limited to, only one side or edge (e.g., an upper portion or a lower portion) of the display panel 110. In one or more embodiments, the data driving circuit 120 may be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The data driving circuit 120 may be connected to an area outward from the display area DA of the display panel 110, or be disposed in the display area DA of the display panel 110.

The gate driving circuit 130 may be a circuit configured to drive a plurality of gate lines GL and can output gate signals to the plurality of gate lines GL.

The gate driving circuit 130 can receive various types of gate driving control signals GCS, and further, receive a first gate voltage corresponding to a turn-on level voltage and a second gate voltage corresponding to a turn-off level voltage. Thereby, the gate driving circuit 130 can generate gate signals and supply the generated gate signals to the plurality of gate lines GL.

In one or more embodiments, the gate driving circuit 130 included in the display device 100 may be embedded into the display panel 110 by a gate-in-panel (GIP) technique. In an example where the gate driving circuit 130 is implemented by the gate-in-panel (GIP) technique, the gate driving circuit 130 may be disposed on the substrate 111 of the display panel 110 during the manufacturing process of the display panel 110 or display device 100.

In one or more embodiments, the gate driving circuit 130 may be disposed in the non-display area NDA of the display panel 110.

In one or more embodiments, the gate driving circuit 130 may be disposed in the display area DA of the display panel 110. In this implementation, for example, the gate driving circuit 130 may be disposed in, and/or electrically connected to, but not limited to, a first area (e.g., a left area or a right area) of the display area DA of the display panel 110. In another example, the gate driving circuit 130 may be disposed in, and/or electrically connected to, but not limited to, a first area (e.g., a left area or a right area) and a second area (e.g., the right area or the left area) of the display area DA of the display panel 110.

Herein, the gate driving circuit 130 embedded in the display panel 110 by the gate-in-panel (GIP) technique may also be referred to as a “gate-in-panel circuit.”

The controller 140 may be a device configured to control the data driving circuit 120 and the gate driving circuit 130, and can control driving timing for the plurality of data lines DL and driving timing for the plurality of gate lines GL.

The controller 140 can supply a data control signal DCS to the data driving circuit 120 to control the data driving circuit 120, and supply a gate control signal GCS to the gate driving circuit 130 to control the gate driving circuit 130.

The controller 140 can receive image data input from a host system 150 and supply image data DATA readable by the data driving circuit 120 based on the input image data to the data driving circuit 120.

The controller 140 may be implemented in a separate component from the data driving circuit 120, or integrated with the data driving circuit 120, so that the controller 140 and the data driving circuit 120 can be implemented in a single integrated circuit.

The controller 140 may be a timing controller used in the typical display technology or a control apparatus/device capable of additionally performing other control functionalities in addition to the typical function of the timing controller. In one or more embodiments, the controller 140 may be one or more other control circuits different from the timing controller, or a circuit or component in the control apparatus/device. The controller 140 may be implemented using various circuits or electronic components such as an integrated circuit (IC), a field programmable gate array (FPGA), an application specific integrated circuit (ASIC), a processor, and/or the like. However, embodiments of the present disclosure are not limited thereto.

The controller 140 may be mounted on a printed circuit board, a flexible printed circuit, or the like, and may be electrically connected to the data driving circuit 120 and the gate driving circuit 130 through the printed circuit board, the flexible printed circuit, and/or the like.

The controller 140 can transmit signals to, and receive signals from, the data driving circuit 120 via one or more predetermined interfaces. For example, such interfaces may include a low voltage differential signaling (LVDS) interface, an embedded clock point-point interface (EPI), a serial peripheral interface (SPI), and the like. However, embodiments of the present disclosure are not limited thereto.

In one or more embodiments, to provide a touch sensing function, as well as an image display function, the display device 100 may include a touch sensor, and a touch sensing circuit configured to sense the touch sensor and detect whether a touch is applied by an object such as a finger, a pen, or the like, or a location of the touch (or touch coordinates).

The touch sensing circuit may include a touch driving circuit configured to drive and sense the touch sensor and generate and output touch sensing data, and a touch controller configured to detect whether a touch is applied or a location of the touch (or touch coordinates) based on the touch sensing data.

The touch sensor may include a plurality of touch electrodes. The touch sensor may further include a plurality of touch lines for electrically connecting the plurality of touch electrodes to the touch driving circuit.

The touch sensor may be disposed outside of the display panel 110 in the form of a touch panel or may be disposed inside of the display panel 110. The touch sensor disposed outside of the display panel 110 may be referred to as an add-on type touch sensor. In the example where the add-on type of touch sensor is disposed in the display device 100, the touch panel and the display panel 110 may be separately manufactured and combined in an assembly process. The add-on type of touch panel may include a touch panel substrate and a plurality of touch electrodes disposed on the touch panel substrate.

In the example where the touch sensor is disposed inside of the display panel 110, the touch sensor may be formed on the substrate along with signal lines and electrodes related to display driving during the manufacturing process of the display panel 110.

The touch driving circuit can supply a touch driving signal to at least one of a plurality of touch electrodes and generate touch sensing data by sensing at least one of the plurality of touch electrodes.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on capacitance between each touch electrode and a touch object (e.g., a finger, a pen, and the like). According to the self-capacitance sensing technique, each of a plurality of touch electrodes can serve as both a driving touch electrode and a sensing touch electrode. The touch driving circuit may drive all, or one or more, of a plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes. According to the mutual-capacitance sensing technique, a plurality of touch electrodes may be divided into driving touch electrodes and sensing touch electrodes. The touch driving circuit can drive the driving touch electrodes and sense the sensing touch electrodes.

In one or more embodiments, the touch driving circuit and touch controller included in the touch sensing circuit may be implemented in separate devices or in a single device. In one or more embodiments, the touch driving circuit and the data driving circuit may be implemented in separate devices or in a single device.

The display device 100 may further include a power supply circuit configured to supply various types of power to the display driving circuit and/or the touch sensing circuit.

In some embodiments, the display device 100 may be a mobile terminal such as a smart phone, a tablet, or the like, or a monitor, a television (TV), or the like. Such devices may be configured in various types, sizes, and shapes. For example, the display device 100 according to embodiments of the present disclosure may be applied to mobile devices, video phones, smart watches, watch phones, wearable devices, foldable devices, rollable devices, bendable devices, flexible devices, stretchable devices, curved devices, sliding devices, variable devices, electronic notebooks, e-books, portable multimedia players (PMP), personal digital assistants (PDA), MP3 players, mobile medical devices, desktop PCs, laptop PCs, netbook computers, workstations, navigation devices, car navigation devices, vehicle display devices, vehicle apparatuses, theater apparatuses, theater display devices, televisions, wallpaper devices, signage devices, game devices, notebook computers, monitors, cameras, camcorders, and home appliances, and the like.

In one or more embodiments, the display device 100 may further include an electronic device such as a camera or image sensor, a sensor capable of detecting an object, ambient light, and the like. For example, the sensor may be a sensor capable of detecting an object or a human body by receiving light such as infrared light, ultrasonic light, ultraviolet light or the like.

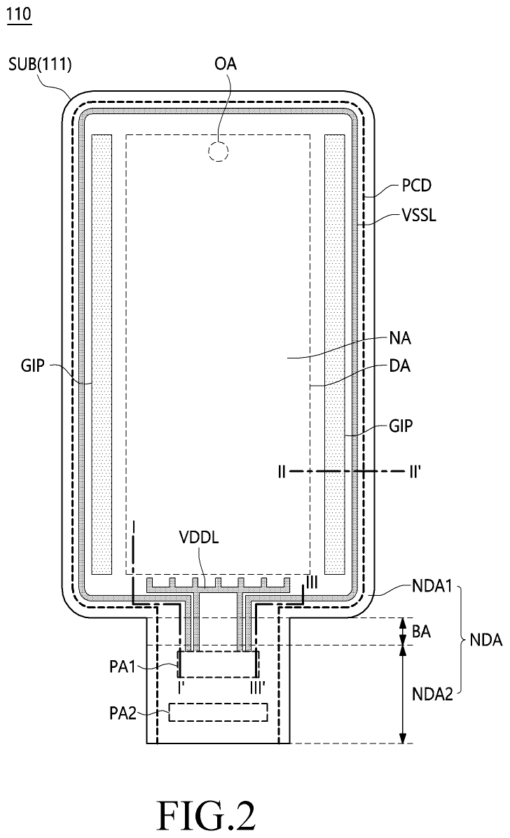

FIG. 2 is an example plan view of the display panel 110 according to embodiments of the present disclosure. In discussions that follow for the configuration of FIG. 2, discussions for features and examples equal, substantially equal, or similar to the features and examples described with reference to FIG. 1 are omitted or briefly described for convenience of description.

Referring to FIG. 2, in one or more example embodiments, all lines and all electrodes included in the display panel 110 may be disposed on a substrate (111, SUB). In one or more embodiments, the substrate (111, SUB) included in the display panel 110 may be a flexible substrate that can be bent in the range of predefined angles. Herein, “bending or bent” may have the same meaning as “folding or folded”, “flexible”, “rollable or rolled”, and the like.

The non-display area NDA may be an area where an image is not displayed and be an area except for the display area DA. For example, subpixels SP may not be disposed in the non-display area NDA. In one or more embodiments, at least one dummy subpixel, which is not directly involved in image displaying, may be disposed in the non-display area NDA.

In one or more embodiments, the non-display area NDA may include a first non-display area NDA1, a bending area BA, and a second non-display area NDA2.

The first non-display area NDA1 may be located adjacent to the display area DA, and be an area that is closest to the display area DA among the first non-display area NDA1, the bending area BA, and the second non-display area NDA2.

The second non-display area NDA2 may include a pad area allowing several pads to be disposed and including, for example, a first pad area PA1 and a second pad area PA2. For example, the second non-display area NDA2 may be located farthest away from the display area DA among the first non-display area NDA1, the bending area BA, and the second non-display area NDA2.

The bending area BA may be an area allowing the substrate (111, SUB) to be bent, and be located between the first non-display area NDA1 and the second non-display area NDA2.

The substrate (111, SUB) may include the display area DA where an image is displayed and the non-display area NDA located outside of the display area DA. A plurality of subpixels SP may be disposed in the display area DA. In one or more embodiments, the non-display area NDA may include a gate-in-panel (GIP) area where a gate driving circuit implemented by a gate-in-panel (GIP) technique is disposed, the bending area BA where a plurality of lines run, the second non-display area NDA2 where a data driving circuit is electrically connected, and the like.

For example, the gate-in-panel (GIP) area may be located in an area adjacent to, or contacting, a left outer edge of the display area DA and/or an area adjacent to, or contacting, a right outer area thereof. In one or more embodiments, the non-display area NDA may include an upper non-display area adjacent to, or contacting, an upper outer edge of the display area DA and a lower non-display area adjacent to, or contacting, a lower outer edge thereof. The second non-display area NDA2 may be an area further outwardly located from the display area DA than the bending area BA, and include the pad area (e.g., including the first pad area PA1 and the second pad area PA2) to which at least one circuit component such as a printed circuit board is electrically connected.

As described above, the substrate (SUB, 111) may include the bending area BA, which can be bent or folded, and when being bent or folded, the bending area BA may be located on the lower surface of a portion of the substrate 111 that is not bent or folded. The bending area BA may be a portion of the non-display area NDA, and be located between a driving circuit area to which a data driving circuit is electrically connected and the display area DA.

In an example subpixel structure, to drive at least one subpixel SP, at least one driving voltage line VDDL for delivering a driving voltage VDD to the at least one subpixel SP and at least one base voltage line VSSL for delivering a base voltage VSS to a common electrode CE of a corresponding light emitting element ED of the at least one subpixel SP may be further disposed on the substrate (SUB, 111).

Referring to FIG. 2, for example, at least one driving voltage line VDDL may be disposed in a column direction, but embodiments of the present disclosure are not limited thereto. To efficiently delivering the driving voltage VDD to the at least one driving voltage line VDDL, at least one driving voltage pattern, which is integrally formed as a single unit with, or electrically connected to, the at least one driving voltage line VDDL, may be disposed in the non-display area NDA.

The at least one driving voltage line VDDL can electrically interconnect, through the at least one driving voltage pattern, the bending area BA and a data driving circuit or a printed circuit board connected to the pad area (e.g., the first pad area PA1 and/or the second pad area PA2).

To efficiently deliver the base voltage VSS, for example, at least one base voltage line VSSL may be disposed in the non-display area NDA such that the at least one base voltage line VSSL surrounds an outer edge of the display area DA. In one or more embodiments, the at least one base voltage line VSSL may pass through the bending area BA and be electrically connected to a data driving circuit or a printed circuit board connected to a driving circuit area.

A crack prevention pattern PCD may be disposed on the substrate (SUB, 111). The crack prevention pattern PCD may be disposed in a portion of the non-display area NDA located further outwardly from the display area DA than the at least one base voltage line VSSL, but embodiments of the present disclosure are not limited thereto.

For example, one or more signal lines among signal lines passing through the bend area BA may be cracked (e.g., electrically disconnected) or form a short circuit with adjacent one or more signal lines when the bending area BA is bent. In this case, since signals cannot be delivered accurately due to the cracked (e.g., electrically disconnected) lines or the short-circuited signal lines, display driving may not be normally performed, which may hinder proper image display and significantly deteriorate image quality. To address these issues, one or more crack prevention patterns PCD may be disposed in the display panel 110. It should be noted that configurations of crack prevention patterns PCD according to embodiments of the present disclosure are not limited thereto.

As described above, the display panel 110 including the flexible substrate (SUB, 111) may allow the bending area BA to which a data drive circuit is connected to be bent. In this configuration, when the bending area BA is bent, a portion of the substrate (SUB, 111) can be folded backwardly or forwardly in the range of certain angles. The folded portion of the bending area BA may be a portion in which an image is not displayed and be invisible in front of the display panel 110. Therefore, as the display panel 110 employs the bending structure and line arrangement structure as in FIG. 2, the display panel 110 can provide advantages of significantly reducing a bezel size of a display device and thereby providing an aesthetic satisfaction.

Referring to FIG. 2, in one or more embodiments, the display area DA defined in the display panel 110 may include a normal area NA and one or more optical areas OA. Several optical electronic components or devices included in the display device 100 may be located in an area overlapping with at least a portion of the optical area OA. One or more optical electronic components or devices may include, for example, one or more of a photographing device such as a camera or an image sensor, a detection sensor such as a proximity sensor, a face recognition sensor, an illuminance sensor, etc., and the like. For example, a camera may be located under the substrate (SUB, 111) of the display panel 110. In one or more embodiments, the camera may be located such that it overlaps with the optical area OA in a plan view.

In one or more embodiments, the one or more optical areas OA may be one or more portions among portions of the display area DA, and light emitting areas EA of subpixels SP for displaying images may be disposed in the one or more optical areas OA. In this configuration, subpixels SP disposed in the normal area NA and subpixels SP disposed in the one or more optical areas OA may have various shapes. For example, the subpixels SP disposed in the normal area NA and the subpixels SP disposed in the one or more optical area OA may have the same shape. In another example, the subpixels SP disposed in the normal area NA and the subpixels SP disposed in the one or more optical area OA may have different shapes. In an example, the subpixels SP disposed in the normal area NA and the subpixels SP disposed in the one or more optical area OA may have different sizes. For example, the subpixels SP disposed in the one or more optical area OA may have a greater size than the subpixels SP disposed in the normal area NA.

FIG. 2 illustrates that one optical area OA is included in the display panel 110, but embodiments of the present disclosure are not limited thereto. For example, one or more optical areas OA included in the display panel 110 may be disposed in various configurations. For example, one or two optical areas OA may be disposed inside of the display area DA. In the example where two optical areas OA are disposed therein, an image capturing device such as a camera or an image sensor may be disposed in a first optical area OA, and a detection sensor or another camera may be disposed in a second optical area OA.

FIG. 2 illustrates that the optical area OA has circular shape, but embodiments of the present disclosure are not limited thereto. For example, the optical area OA may have various shapes such as a circular, oval, square, hexagonal, or octagonal shape. In an example when a plurality of optical areas OA are disposed inside of the display area DA, a first optical area OA and one or more remaining optical area OA (e.g., a second optical area OA2) may have different sizes. For example, the first optical area OA where the image capturing device such as a camera or an image sensor is disposed may have a greater size than the second optical area OA where the detection sensor or the like is disposed, but not limited thereto.

In one or more embodiments, the display panel 110 can reduce an area of the bezel area and increase or maximize the display area DA by including a structure where one or more optical areas OA are located in the display area DA.

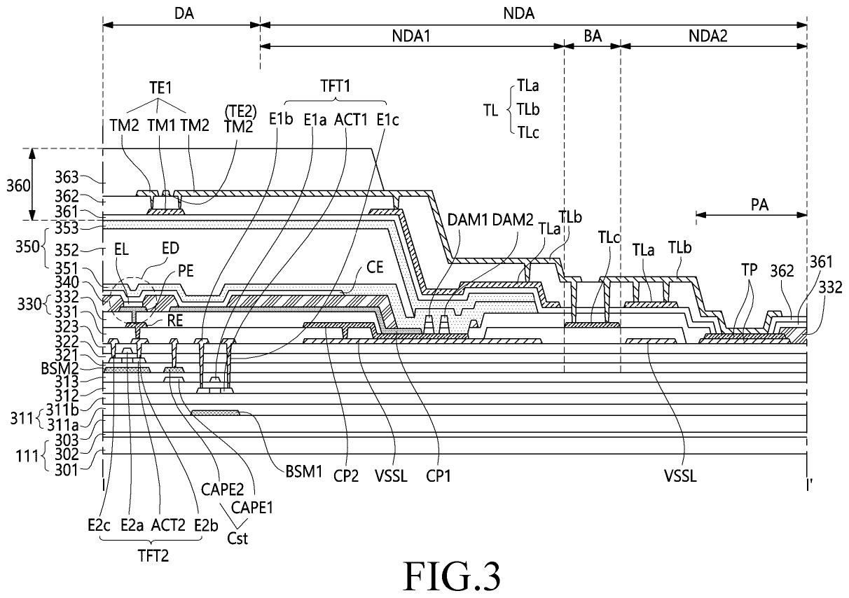

FIG. 3 is an example plan view of the display panel 110 according to embodiments of the present disclosure. FIG. 3 illustrates an example cross-sectional view taken along line I-I′ of FIG. 2. In discussions that follow for the configuration of FIG. 3, discussions for features and examples equal, substantially equal, or similar to the features and examples described with reference to FIGS. 1 and 2 are omitted or briefly described for convenience of description.

Referring to FIG. 3, in one or more example embodiments, the display panel 110 may include the substrate 111, a transistor part, a light emitting element part, and an encapsulation part, but embodiments of the present disclosure are not limited thereto.

The substrate 111 may include a plastic material having flexibility and may have a flexible characteristic, for example, the substrate may include a flexible polymer film. For example, the flexible polymer film may be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto. The substrate 111 may include a single layer or multilayer. In an example where the substrate 111 includes a multilayer, the substrate 111 may include a first substrate 301, an intermediate substrate layer 302, and a second substrate 303. The intermediate substrate layer 302 may be located between the first substrate 301 and the second substrate 303. In one or more embodiments, each of the first substrate 301 and the second substrate 303 may be a polyimide (PI) layer, but embodiments of the present disclosure are not limited thereto. The intermediate substrate layer 302 may be an inorganic insulating layer, but embodiments of the present disclosure are not limited thereto. When electric charges are stored on the first substrate 301, which is a polyimide (PI) layer, the intermediate substrate layer 302 can block the charges from affecting transistors on the second substrate 303 through the second substrate 303, which is a polyimide (PI) layer.

The intermediate substrate layer 302 can block moisture from moving upwardly through the first substrate 301. For example, the intermediate substrate layer 302 may be in the form of a single layer of silicon nitride (SiNx) or silicon oxide (SiOx) or multiple layers thereof, or be in the form of double layers of silicon dioxide (SiO₂) and silicon nitride (SiNx). For example, the intermediate substrate layer 302 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but embodiments of the present disclosure are not limited thereto. The transistor part may include insulating layers (311, 312, 313, 321, 322, and 323), thin film transistors (TFT1 and TFT2), a storage capacitor Cst, and several electrodes or signal lines, on the substrate 111.

The thin film transistors (TFT1 and TFT2) included in the transistor part may include a first thin film transistor TFT1 and a second thin film transistor TFT2.

The first thin film transistor TFT1 may include a first active layer ACT1, a first electrode E1a, a second electrode E1b, and a third electrode E1c.

The first electrode E1a may be a gate electrode, the second electrode E1b may be a source electrode or a drain electrode, and the third electrode E1c may be the drain electrode or the source electrode. Hereinafter, for convenience of explanation, discussions may be provided based on examples where the first, second, and third electrodes (E1a, E1b, and E1c) are a first gate electrode E1a, a first source electrode E1b, and a first drain electrode E1c, respectively. However, embodiments of the present disclosure are not limited thereto.

The first active layer ACT1 may include a first semiconductor material. For example, the first semiconductor material may include an oxide semiconductor, amorphous silicon, polysilicon, low-temperature polysilicon (LTPS), or the like, but embodiments of the present disclosure are not limited thereto. The first thin film transistor TFT1 may be implemented as a p-channel transistor or an n-channel transistor, but embodiments of the present disclosure are not limited thereto.

The second thin film transistor TFT2 may include a second active layer ACT2, a fourth electrode E2a, a fifth electrode E2b, and a sixth electrode E2c.

The fourth electrode E2a may be a gate electrode, the fifth electrode E2b may be a source electrode or a drain electrode, and the sixth electrode E2c may be the drain electrode or the source electrode. Hereinafter, for convenience of explanation, discussions may be provided based on examples where the fourth, fifth, and sixth electrodes (E2a, E2b, and E2c) are a second gate electrode E2a, a second source electrode E2b, and a second drain electrode E2c, respectively. However, embodiments of the present disclosure are not limited thereto.

The second active layer ACT2 may include a second semiconductor material. For example, the second semiconductor material may include an oxide semiconductor, amorphous silicon, polysilicon, or low-temperature polysilicon (LTPS), or the like, but embodiments of the present disclosure are not limited thereto. The second thin film transistor TFT2 may be implemented as a p-channel transistor or an n-channel transistor, but embodiments of the present disclosure are not limited thereto.

The types of semiconductor materials of each of the first active layer ACT1 of the first thin film transistor TFT1 and the second active layer ACT2 of the second thin film transistor TFT2 may be as follows.

For example, the first active layer ACT1 of the first thin film transistor TFT1 and the second active layer ACT2 of the second thin film transistor TFT2 may include an oxide semiconductor material. For example, the first active layer ACT1 of the first thin film transistor TFT1 and the second active layer ACT2 of the second thin film transistor TFT2 may include a low-temperature polysilicon semiconductor material. In another example, the first active layer ACT1 of the first thin film transistor TFT1 may include a low-temperature polysilicon semiconductor material, and the second active layer ACT2 of the second thin film transistor TFT2 may include an oxide semiconductor material. In another example, the first active layer ACT1 of the first thin film transistor TFT1 may include an oxide semiconductor material, and the second active layer ACT2 of the second thin film transistor TFT2 may include a low-temperature polysilicon semiconductor material.

Transistors disposed in the display area DA may be used as follows.

For example, all transistors included in each subpixel SP may be implemented as the first thin film transistor TFT1. For example, all transistors included in each subpixel SP may be implemented as the second thin film transistor TFT2. For example, one or more of transistors included in each subpixel SP may be implemented as the first thin film transistor TFT1, and the remaining one or more transistors may be implemented as the second thin film transistor TFT2. For example, each subpixel SP may include at least one first thin film transistor TFT1 and at least one second thin film transistor TFT2.

One or more of transistors included in each subpixel SP may be implemented as the first thin film transistor TFT1, and the remaining one or more transistors may be implemented as the second thin film transistor TFT2.

For example, in each subpixel SP, a driving transistor DT may be implemented as the first thin film transistor TFT1, and the remaining one or more transistors (e.g., a scan transistor ST, an emission control transistor, and/or the like) except for the driving transistor DT may be implemented as the second thin film transistor TFT2.

For example, in each subpixel SP, a driving transistor DT may be implemented as the second thin film transistor TFT2, and the remaining one or more transistors (e.g., a scan transistor ST, an emission control transistor, and/or the like) except for the driving transistor DT may be implemented as the first thin film transistor TFT1.

In FIG. 3, the second thin film transistor TFT2 connected to a pixel electrode PE of a light emitting element ED may be a driving transistor DT or a transistor different from the driving transistor DT depending on the configuration of a corresponding subpixel circuit SPC. For example, in FIG. 3, the second thin film transistor TFT2 connected to the pixel electrode PE of the light emitting element ED may be a light emitting control transistor connected between a driving transistor DT and the light emitting element ED.

Transistors disposed in the non-display area NDA may be used as follows.

For example, the active layers of transistors included in the gate driving circuit 130 of the gate-in-panel (GIP) type may include an oxide semiconductor material. For example, the active layers of transistors included in the gate driving circuit 130 of the gate-in-panel (GIP) type may include a low-temperature polysilicon semiconductor material. For example, among the active layers of transistors included in the gate driving circuit 130 of the gate-in-panel (GIP) type, some active layers may include a low-temperature polysilicon semiconductor material, and other active layers or the remaining active layers may include an oxide semiconductor material.

The second active layer ACT2 of the second thin film transistor TFT2 may be located higher from the substrate 111 than the first active layer ACT1 of the first thin film transistor TFT1.

A first buffer layer 311 may be disposed under the first active layer ACT1 of the first thin film transistor TFT1, and a second buffer layer 321 may be disposed under the second active layer ACT2 of the second thin film transistor TFT2. Each of the first buffer layer 311 and second buffer layer 321 may include at least one of silicone oxide (SiOx), silicone nitride (SiNx), and silicone oxynitride (SiOxNy). For example, the first active layer ACT1 of the first thin film transistor TFT1 may be disposed on the first buffer layer 311, and the second active layer ACT2 of the second thin film transistor TFT2 may be disposed on the second buffer layer 321. The second buffer layer 321 may be disposed on the first buffer layer 311.

A storage capacitor Cst may be disposed in several metal layers in the display panel 110. For example, the storage capacitor Cst may include a first capacitor electrode CAPE1 and a second capacitor electrode CAPE2.

The light emitting element part may include a plurality of light emitting elements ED disposed on a planarization layer 330. Each of the plurality of light emitting elements ED may include a pixel electrode PE, an intermediate layer EL, and a common electrode CE.

The encapsulation part may include an encapsulation layer 350 on a plurality of light emitting elements ED. The encapsulation layer 350 may be in the form of a single layer or multilayer, but embodiments of the present disclosure are not limited thereto. For example, the encapsulation layer may include a first inorganic encapsulation layer, a first organic encapsulation layer, and a second inorganic encapsulation layer, Alternatively, the encapsulation layer may include a first inorganic encapsulation layer, a first organic encapsulation layer, a second inorganic encapsulation layer, a second organic encapsulation layer, and a third inorganic encapsulation layer stacked sequentially.

The first inorganic encapsulation layer, the second inorganic encapsulation layer, and the third inorganic encapsulation layer may serve to block the penetration of moisture or oxygen. The first inorganic encapsulation layer, the second inorganic encapsulation layer, and the third inorganic encapsulation layer may be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer may each have a larger thickness than each of the first inorganic encapsulation layer, the second inorganic encapsulation layer, and the third inorganic encapsulation layer in order to adsorb or block particles that may be produced during a process of manufacturing the display device. The first organic encapsulation layer and the second organic encapsulation layer may fill cracks that may be formed in the first inorganic encapsulation layer and the second inorganic encapsulation layer. The first organic encapsulation layer and the second organic encapsulation layer may planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer may planarize an upper portion of the first inorganic encapsulation layer by covering particles on the first inorganic encapsulation layer. For example, the second organic encapsulation layer may planarize an upper portion of the second inorganic encapsulation layer by covering particles on the second inorganic encapsulation layer. The first organic encapsulation layer and the second organic encapsulation layer may be made of an organic material, and for example, epoxy polymer, acrylic polymer, or the like may be used. However, the present disclosure is not limited thereto.

Meanwhile, the encapsulation layer is not limited to three or five layers, for example, n layers alternately stacked between inorganic encapsulation layer and organic encapsulation layer (where n is an integer greater than 3) may be included.

In addition to the encapsulation layer 350, the encapsulation part may further include at least one dam DAM to prevent a material included in the encapsulation layer 350 from overflowing. For example, in an example where the encapsulation layer 350 includes a first encapsulation layer 351, a second encapsulation layer 352, and a third encapsulation layer 353, and the second encapsulation layer 352 is an organic encapsulation layer including an organic material, the dam DAM can prevent the organic encapsulation layer from overflowing during the process of manufacturing the display panel 110.

Hereinafter, a vertical structure or stack-up structure of the display panel 110 is described in more detail with reference to FIG. 3.

Referring to FIG. 3, the first buffer layer 311 may be disposed on the substrate 111. The first buffer layer 311 may be in the form of a single layer or multilayer, but embodiments of the present disclosure are not limited thereto. In an example where the first buffer layer 311 is in the form of a multilayer, the first buffer layer 311 may include a lower buffer layer 311a and an upper buffer layer 311b.

The first active layer ACT1 of the first thin film transistor TFT1 may be disposed on the first buffer layer 311. The first active layer ACT1 may include a channel region where a channel is formed, a source connection region on a first side of the channel region, and a drain connection region on an opposing second side of the channel region.

A first gate insulating layer 312 may be disposed on the first active layer ACT1 of the first transistor TFT1. The first gate insulating layer 312 may include at least one of silicone oxide (SiOx), silicone nitride (SiNx), and silicone oxynitride (SiOxNy). For example, the first gate insulating layer 312 may be configured as a single layer or multi-layer of silicone oxide (SiOx), silicone nitride (SiNx), or silicone oxynitride (SiOxNy), for example, the first gate insulating layer 312 may be formed by inorganic film in a single layer or in multiple layers, for example, the inorganic film in a single layer may be a silicone oxide (SiOx) film, a silicone nitride (SiNx) film or a silicone oxynitride (SiOxNy), and inorganic films in multiple layers may formed by alternately stacking at least one of one or more silicone oxide (SiOx) films, one or more silicone nitride (SiNx) films and one or more silicone oxynitride (SiOxNy) films, and one or more amorphous silicon (a-Si), but the example embodiments of the present disclosure are not limited thereto. The first gate electrode E1a of the first thin transistor TFT1 may be disposed on the first gate insulating layer 312. A first interlayer insulating layer 313 may be disposed on the first gate electrode E1a of the first thin film transistor TFT1. The first interlayer insulating layer 313 may include at least one of silicone oxide (SiOx), silicone nitride (SiNx), and silicone oxynitride (SiOxNy). For example, the first interlayer insulating layer 313 may be configured as a single layer or multi-layer of silicone oxide (SiOx), silicone nitride (SiNx), or silicone oxynitride (SiOxNy), for example, the first interlayer insulating layer 313 may be formed by inorganic film in a single layer or in multiple layers, for example, the inorganic film in a single layer may be a silicone oxide (SiOx) film, a silicone nitride (SiNx) film or a silicone oxynitride (SiOxNy), and inorganic films in multiple layers may formed by alternately stacking at least one of one or more silicone oxide (SiOx) films, one or more silicone nitride (SiNx) films and one or more silicone oxynitride (SiOxNy) films, and one or more amorphous silicon (a-Si), but the example embodiments of the present disclosure are not limited thereto. A metal layer in which the first gate electrode E1a of the first thin film transistor TFT1 is disposed may be referred to as a first gate metal layer.

The second buffer layer 321 may be disposed on the first interlayer insulating layer 313.

The second active layer ACT2 of the second thin film transistor TFT2 may be disposed on the second buffer layer 321. The second active layer ACT2 may include a channel region where a channel is formed, a source connection region on a first side of the channel region, and a drain connection region on an opposing second side of the channel region.

A second gate insulating layer 322 may be disposed on the second active layer ACT2 of the second thin film transistor TFT2. The second gate insulating layer 322 may include at least one of silicone oxide (SiOx), silicone nitride (SiNx), and silicone oxynitride (SiOxNy). For example, the second gate insulating layer 322 may be configured as a single layer or multi-layer of silicone oxide (SiOx), silicone nitride (SiNx), or silicone oxynitride (SiOxNy), for example, the second gate insulating layer 322 may be formed by inorganic film in a single layer or in multiple layers, for example, the inorganic film in a single layer may be a silicone oxide (SiOx) film, a silicone nitride (SiNx) film or a silicone oxynitride (SiOxNy), and inorganic films in multiple layers may formed by alternately stacking at least one of one or more silicone oxide (SiOx) films, one or more silicone nitride (SiNx) films and one or more silicone oxynitride (SiOxNy) films, and one or more amorphous silicon (a-Si), but the example embodiments of the present disclosure are not limited thereto. The second gate electrode E2a of the second thin film transistor TFT2 may be disposed on the second gate insulating layer 322. A second interlayer insulating layer 323 may be disposed on the second gate electrode E2a of the second thin film transistor TFT2. The second interlayer insulating layer 323 may include at least one of silicone oxide (SiOx), silicone nitride (SiNx), and silicone oxynitride (SiOxNy). For example, the second interlayer insulating layer 323 may be configured as a single layer or multi-layer of silicone oxide (SiOx), silicone nitride (SiNx), or silicone oxynitride (SiOxNy), for example, the second interlayer insulating layer 323 may be formed by inorganic film in a single layer or in multiple layers, for example, the inorganic film in a single layer may be a silicone oxide (SiOx) film, a silicone nitride (SiNx) film or a silicone oxynitride (SiOxNy), and inorganic films in multiple layers may formed by alternately stacking at least one of one or more silicone oxide (SiOx) films, one or more silicone nitride (SiNx) films and one or more silicone oxynitride (SiOxNy) films, and one or more amorphous silicon (a-Si), but the example embodiments of the present disclosure are not limited thereto. The second gate electrode E2a of the second thin film transistor TFT2 may be referred to as a second gate metal layer.

The first source electrode E1b and the first drain electrode E1c of the first thin film transistor TFT1 and the second source electrode E2b and the second drain electrode E2c of the second thin film transistor TFT2 may be disposed on the second interlayer insulating layer 323.

The first source electrode E1b and the first drain electrode E1c of the first thin film transistor TFT1 may be connected to the source connection region and the drain connection region of the first active layer ACT1, respectively, through holes of the second interlayer insulating layer 323, the second gate insulating layer 322, the second buffer layer 321, the first interlayer insulating layer 313, and the first gate insulating layer 312.

The second source electrode E2b and the second drain electrode E2c of the second thin film transistor TFT2 may be connected to the source connection region and the drain connection region of the second active layer ACT2, respectively, through holes of the second interlayer insulating layer 323 and the second gate insulating layer 322.

The first source electrode E1b and the first drain electrode E1c of the first thin film transistor TFT1, and the second source electrode E2b and the second drain electrode E2c of the second thin film transistor TFT2 may include a first source-drain metal and be disposed in a first source-drain metal layer.

Referring to FIG. 3, in one or more embodiments, the storage capacitor Cst may include the first capacitor electrode CAPE1 and the second capacitor electrode CAPE2. For example, the storage capacitor Cst may include three or more capacitor electrodes, and may include two or more capacitors connected in parallel.

Each of the first capacitor electrode CAPE1 and the second capacitor electrode CAPE2 may be disposed in several metal layers disposed in the display panel 110.

In one or more embodiments, the first capacitor electrode CAPE1 may include the same first gate metal as the first gate electrode E1a of the first thin film transistor TFT1 on the first gate insulating layer 312 and may be disposed in the first gate metal layer, but embodiments of the present disclosure are not limited thereto. In one or more embodiments, the second capacitor electrode CAPE2 may be disposed on the first interlayer insulating layer 313.

The second source electrode E2b of the second transistor TFT2 may be electrically connected to the second capacitor electrode CAPE2 through holes of the second interlayer insulating layer 323, the second gate insulating layer 322, and the second buffer layer 321.

Referring to FIG. 3, the transistor part may further include a first shield pattern BSM1 disposed on the substrate 111. The first shield pattern BSM1 may overlap with the first active layer ACT1 of the first thin film transistor TFT1. The first shield pattern BSM1 may be disposed under the first active layer ACT1 of the first thin film transistor TFT1. For example, the first shield pattern BSM1 may be disposed between the substrate 111 and the first buffer layer 311, or may be disposed between the lower buffer layer 311a and the upper buffer layer 311b.

The transistor part may further include a second shield pattern BSM2 disposed on the substrate 111. The second shield pattern BSM2 may overlap with the second active layer ACT2 of the second thin film transistor TFT2. The second shield pattern BSM2 may be disposed under the second active layer ACT2 of the second thin film transistor TFT2. For example, the second shield pattern BSM2 may be disposed in a metal layer between the first interlayer insulating layer 313 and the second buffer layer 321. The second shield pattern BSM2 may be disposed in the same metal layer as the second capacitor CAPE2, but embodiments of the present disclosure are not limited thereto. For example, the second shield pattern BSM2 may be disposed in the same first gate metal layer as the first gate electrode E1a of the first thin film transistor TFT1.

The planarization layer 330 may be disposed on the first thin film transistor TFT1 and the second thin film transistor TFT2, and may be disposed under the light emitting element ED. The planarization layer 330 may be an organic insulating layer including an organic insulating material. For example, the planarization layer 330 can be formed of an organic layer such as an acryl-based material, an epoxy-based material, a phenolic-based material, a polyamide-based material, or a polyimide-based material, but example embodiments of the present disclosure are not limited thereto.

For example, the planarization layer 330 may be in the form of a single layer. For example, the planarization layer 330 may be in the form of two layers. The planarization layer 330 may include a first planarization layer 331 and a second planarization layer 332. For example, the planarization layer 330 may be in the form of three or more layers. However, embodiments of the present disclosure are not limited thereto.

Referring to FIG. 3, the first planarization layer 331 may be disposed on the first source electrode E1b and the first drain electrode E1c of the first thin film transistor TFT1 and the second source electrode E2b and the second drain electrode E2c of the second thin film transistor TFT2. For example, the first planarization layer 331 may be disposed on the first thin film transistor TFT1 and the second thin film transistor TFT2. For example, the first planarization layer 331 may be disposed such that it covers both the first thin film transistor TFT1 and the second thin film transistor TFT2.

Referring to FIG. 3, a connection electrode RE may be disposed on the first planarization layer 331. The connection electrode RE may electrically interconnect the second source electrode E2b of the second thin film transistor TFT2 and the pixel electrode PE.

The connection electrode RE may be electrically connected to the second source electrode E2b of the second thin film transistor TFT2 through a hole of the first planarization layer 331. The second source electrode E2b of the second thin film transistor TFT2 may be electrically connected to the second capacitor electrode CAPE2 of the storage capacitor Cst.

The connection electrode RE may be disposed in a second source-drain metal layer on the first planarization layer 331.

The second planarization layer 332 may be disposed on the connection electrode RE.

Referring to FIG. 3, the light emitting element part may be disposed on the second planarization layer 332. The light emitting element ED may be formed on the second planarization layer 332. The light emitting element ED may include the pixel electrode PE, the intermediate layer EL, and the common electrode CE. A light emitting area of the light emitting element ED may be formed by an area where the pixel electrode PE, the intermediate layer EL, and the common electrode CE overlap and contact each other.

The pixel electrode PE may be disposed on the second planarization layer 332. The pixel electrode PE may be electrically connected to the connection electrode RE through a hole of the second planarization layer 332.

The bank 340 may be disposed on the pixel electrode PE. An opening of the bank 340 may expose a portion of the pixel electrode PE to form a light emitting area. The opening of the bank 340 may overlap with a portion of the pixel electrode PE.

For example, the bank 340 may include a material including a black pigment, or an organic material including a benzocyclobutene resin, a polyimide resin, an acrylic resin, a photosensitive polymer, or the like. In an example where the bank 340 includes a material including a black pigment or a black dye, the bank 340 may be a black bank. In the example where the bank 340 includes a material including a black pigment or a black dye, the luminance of the display device 100 can be further improved because light from the outside or light reflected from the outside can be blocked.

The intermediate layer EL of the light emitting element ED may be disposed on a portion of the pixel electrode PE and the bank 340. The common electrode CE may be disposed on the intermediate layer EL.

Referring to FIG. 3, the encapsulation part may be disposed on the light emitting element part, and be located on the common electrode CE. The encapsulation part may include an encapsulation layer 350 disposed on the common electrode CE.

The encapsulation layer 350 can prevent moisture or oxygen from penetrating into the light emitting element ED. For example, the encapsulation layer 350 can prevent moisture or oxygen from penetrating into an organic material included in the intermediate layer EL of the light emitting element ED. In one or more embodiments, the encapsulation layer 350 may be in the form of a single layer or multilayer, but embodiments of the present disclosure are not limited thereto. For example, the encapsulation layer may include a first inorganic encapsulation layer, a first organic encapsulation layer, and a second inorganic encapsulation layer, Alternatively, the encapsulation layer may include a first inorganic encapsulation layer, a first organic encapsulation layer, a second inorganic encapsulation layer, a second organic encapsulation layer, and a third inorganic encapsulation layer stacked sequentially.

The first inorganic encapsulation layer, the second inorganic encapsulation layer, and the third inorganic encapsulation layer may serve to block the penetration of moisture or oxygen. The first inorganic encapsulation layer, the second inorganic encapsulation layer, and the third inorganic encapsulation layer may be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer may each have a larger thickness than each of the first inorganic encapsulation layer, the second inorganic encapsulation layer, and the third inorganic encapsulation layer in order to adsorb or block particles that may be produced during a process of manufacturing the display device. The first organic encapsulation layer and the second organic encapsulation layer may fill cracks that may be formed in the first inorganic encapsulation layer and the second inorganic encapsulation layer. The first organic encapsulation layer and the second organic encapsulation layer may planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer may planarize an upper portion of the first inorganic encapsulation layer by covering particles on the first inorganic encapsulation layer. For example, the second organic encapsulation layer may planarize an upper portion of the second inorganic encapsulation layer by covering particles on the second inorganic encapsulation layer. The first organic encapsulation layer and the second organic encapsulation layer may be made of an organic material, and for example, epoxy polymer, acrylic polymer, or the like may be used. However, the present disclosure is not limited thereto.

Meanwhile, the encapsulation layer is not limited to three or five layers, for example, n layers alternately stacked between inorganic encapsulation layer and organic encapsulation layer (where n is an integer greater than 3) may be included.

For example, the encapsulation layer 350 may include a first encapsulation layer 351, a second encapsulation layer 352, and a third encapsulation layer 353. For example, the first encapsulation layer 351 and the third encapsulation layer 353 may include an inorganic material, and the second encapsulation layer 352 may include an organic material. However, embodiments of the present disclosure are not limited thereto.

In one or more embodiments, a touch sensor may be embedded in the display panel 110. In this implementation, the display panel 110 may include a touch sensor layer 360 disposed on the encapsulation layer 350 and including a touch sensor.

Referring to FIG. 3, the touch sensor layer 360 may include a plurality of touch electrodes TE serving as the touch sensor, and include at least one touch metal layer for forming the plurality of touch electrodes TE.

For example, to form the plurality of touch electrodes TE, the touch sensor layer 360 may include a first touch metal layer in which a plurality of first touch metals TM1 are disposed, and a second touch metal layer in which a plurality of second touch metals TM2 are disposed. In this implementation, the touch sensor layer 360 may further include a touch interlayer insulating layer 362 disposed between the first touch metal layer and the second touch metal layer.

For example, one of the first touch metal layer and the second touch metal layer may be a sensor metal layer, and the other may be a bridge metal layer.

For example, the first touch metal layer may be a bridge metal layer, and the second touch metal layer may be a sensor metal layer. In this implementation, the plurality of second touch metals TM2 disposed in the second touch metal layer may be sensor metals forming the touch sensor, and the plurality of first touch metals TM1 disposed in the first touch metal layer may be bridge metals electrically connecting the plurality of second touch metals TM2, which are the sensor metals. For example, two or more second touch metals TM2 and at least one first touch metal TM1 may form one first touch electrode TE1. In this implementation, the two or more second touch electrodes TE2 may be electrically connected by at least one first touch metal TM1.

In another example, the first touch metal layer may be a sensor metal layer, and the second touch metal layer may be a bridge metal layer. In this implementation, the plurality of first touch metals TM1 disposed in the first touch metal layer may be sensor metals forming the touch sensor, and the plurality of second touch metals TM2 disposed in the second touch metal layer may be bridge metals electrically connecting the plurality of first touch metals TM1, which are the sensor metals.

In another example, each of the first touch metal layer and the second touch metal layer may be a sensor metal layer and a bridge metal layer. For example, the first touch metal layer may be a sensor metal layer and a bridge metal layer, and the second touch metal layer may be a sensor metal layer and a bridge metal layer. In this implementation, the plurality of first touch metals TM1 disposed in the first touch metal layer may include sensor metals and bridge metals, and the plurality of second touch metals TM2 disposed in the second touch metal layer may include sensor metals and bridge metals.

Referring to FIG. 3, the touch sensor layer 360 may further include a touch buffer layer 361 disposed on the encapsulation layer 350. The touch buffer layer 361 may be disposed between the encapsulation layer 350 and the touch metal layer. For example, the first touch metal layer may be disposed on the touch buffer layer 361, and the touch interlayer insulating layer 362 may be disposed on the first touch metal layer.

Referring to FIG. 3, the touch sensor layer 360 may further include a touch protection layer 363 disposed such that the touch protection layer 363 covers the touch metal layers. For example, the touch protection layer 363 may be disposed on the second touch metal layer.

For example, the touch buffer layer 361 may be an inorganic layer including an inorganic insulating material or an organic layer including an organic insulating material. The touch interlayer insulating layer 362 may be an inorganic layer including an inorganic insulating material or an organic layer including an organic insulating material. The touch protection layer 363 may be an inorganic layer including an inorganic insulating material or an organic layer including an organic insulating material. For example, the inorganic layer may include inorganic material such as silicone oxide (SiOx), silicone nitride (SiNx), or silicone oxynitride (SiOxNy). For example, the organic layer may include an organic material such as an acryl-based material, an epoxy-based material, a phenolic-based material, a polyamide-based material, or a polyimide-based material. However, the present disclosure is not limited thereto

For example, at least one of the touch buffer layer 361 and the touch interlayer insulating layer 362 may be disposed to extend from the display area DA to the non-display area NDA. The touch protection layer 363 may be disposed to extend from the display area DA to the non-display area NDA.

A touch routing line TL may electrically connect a touch electrode TE and a touch pad TP. The touch routing line TL may be formed by at least one of the first touch metal TM1 and the second touch metal TM2.

For example, the touch routing line TL may be formed by the first touch metal TM1. For example, the touch routing line TL may be formed by the second touch metal TM2. For example, the touch routing line TL may be formed by the first touch metal TM1 and the second touch metal TM2. In an example where one touch routing line TL is formed by the first touch metal TM1 and the second touch metal TM2, the first touch metal TM1 and the second touch metal TM2 included in the touch routing line TL may be electrically connected through a hole in the insulating layer 362.

For example, one touch routing line TL may include a plurality of line portions, and each of the plurality of line portions may be a single line portion or a double line portion. For example, the single line portion may be a line portion with one signal path, and the double line portion may be a line portion with two signal paths connected in parallel.

The touch routing line TL may extend along an inclined surface of the encapsulation layer 350, extend over an upper portion of at least one dam (DAM1 and/or DAM2), and reach a touch pad TP.

The touch buffer layer 361 may have an opening to expose at least a portion of the touch pad TP. The touch routing line TL may be electrically connected to the touch pad TP through the opening of the touch buffer layer 361. The touch interlayer insulating layer 362 may be disposed on a portion of the touch routing line TL and may extend to an area where the touch pad TP is disposed. The touch protection layer 363 may be disposed only in the display area DA, or may extend to the non-display area NDA and be disposed on the touch routing line TL. In one or more embodiments, the touch protection layer 363 may extend further to an upper portion of the touch pad TP.

Each of a plurality of touch electrodes TE may be a mesh-type electrode configured to have a mesh and having a plurality of openings. In this implementation, each of the plurality of touch electrodes TE may include at least one second touch metal TM2. However, embodiments of the present disclosure are not limited thereto.

For example, the plurality of touch electrodes TE may include at least one first touch electrode TE1 and at least one second touch electrode TE2. In an example where the first touch metal layer is a bridge metal layer and the second touch metal layer is a sensor metal layer, two or more second touch metals TM2 included in a first touch electrode TE1, which is the touch sensor, may be electrically connected through at least one first touch metal TM1, which is the bridge metal. For example, two second touch metals TM2 spaced apart from each other may be electrically connected by a first touch metal TM1 to form one first touch electrode TE1.

Referring to FIG. 3, the plurality of first touch metals TM1 and the plurality of second touch metals TM2 may be disposed not to overlap with the light emitting element ED. The plurality of first touch metals TM1 and the plurality of second touch metals TM2 may overlap with the bank 340. According to these configurations, the display panel 110 can provide an advantage of improving the emission efficiency of the light emitting element ED.

Referring to FIG. 3, the touch routing line TL may connect the touch pad TP disposed in a pad area PA of a second non-display area NDA2 and the first touch electrode TE1 disposed in the display area DA. In this implementation, the touch routing line TL may be disposed across the second non-display area NDA2, the bending area BA, and the first non-display area NDA1.

The touch routing line TL may include a first line portion TLa, a second line portion TLb, and a third line portion TLc. For example, the touch routing line TL may include the first line portion TLa and the second line portion TLb disposed in the first non-display area NDA1 and the second non-display area NDA2, and the third line portion TLc disposed in the bending area BA. The third line portion TLc may interconnect the first line portion TLa and the second line portion TLb.

The first line portion TLa of the touch routing line TL may be a single line portion and further include a third touch metal layer in which a third touch metal TM3 is disposed.

The first line portion TLa of the touch routing line TL may be disposed to extend along an inclined surface of the encapsulation layer 350, and further extend over at least one dam (DAM1 and/or DAM2).

For example, the first line portion TLa of the touch routing line TL may be connected to the third line portion TLc of the touch routing line TL through at least one of the first touch metal layer and the second touch metal layer.

The second line portion TLb of the touch routing line TL may include at least one of the first touch metal layer on which the first touch metal TM1 is disposed and the second touch metal layer on which the second touch metal TM2 is disposed.

For example, the second line portion TLb of the touch routing line TL may be formed by the second touch metal layer. For another example, the second line portion TLb of the touch routing line TL may be formed by an electrical connection of the first touch metal layer and the second touch metal layer.

For example, the second line portion TLb of the touch routing line TL may be electrically connected to the touch pad TP through a contact hole (opening) through the second planarization layer 532, the touch buffer layer 551, and the touch interlayer insulation layer 552.

For example, the third line portion TLc of the touch routing line TL may be connected to the second line portion TLb of the touch routing line TL.

The third line portion TLc of the touch routing line TL may include a metal layer different from the first to third touch metal layers in which the first to third touch metals (TM1, TM2, and TM3) are disposed. For example, the metal layer included in the third line portion TLc of the touch routing line TL may be the same as a metal layer in which one or more electrodes or lines for display driving are disposed. For example, the metal layer included in the third line portion TLc of the touch routing line TL may include a metal layer in which the pixel electrode PE is disposed, but embodiments of the present disclosure are not limited thereto.

The touch pad TP may be electrically connected to the second line portion TLb of the touch routing line TL and may include a metal layer different from the first to third touch metal layers. For example, the metal layer included in the touch pad TP may be the same as a metal layer in which one or more electrodes or lines for display driving are disposed. For example, the metal layer included in the touch pad TP may include a metal layer in which the pixel electrode PE is disposed, but embodiments of the present disclosure are not limited thereto.

Referring to FIG. 3, in one or more embodiments, the display panel 110 may further include a common voltage line VSSL for delivering a common voltage VSS, and a connection pattern for connecting the common electrode CE and the common voltage line VSSL.

For example, the connection pattern may include a first connection pattern CP1 and a second connection pattern CP2.

For example, the first connection pattern CP1 may interconnect the common electrode CE and the second connection pattern CP2, and the second connection pattern CP2 may interconnect the first connection pattern CP1 and the first common voltage line VSSL, but embodiments of the present disclosure are not limited thereto.

For example, the first connection pattern CP1 may include the same material as the pixel electrode PE. The second connection pattern CP2 may include the same material as the connection electrode RE.

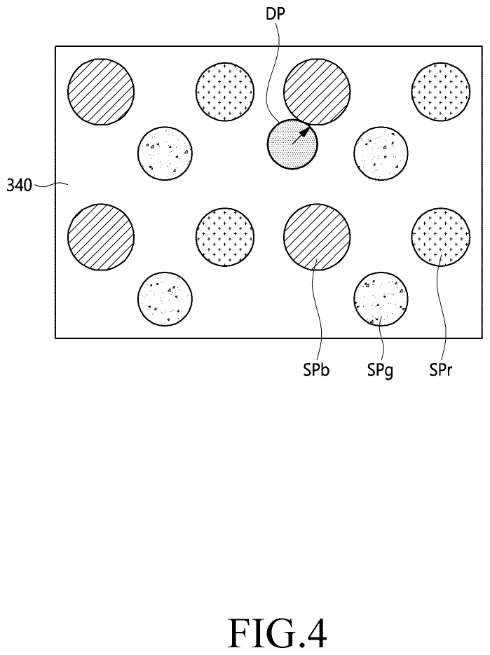

FIG. 4 is an example plan view of an area of the display panel 110 according to embodiments of the present disclosure. In discussions that follow for the configuration of FIG. 4, discussions for features and examples equal, substantially equal, or similar to the features and examples described with reference to FIGS. 1 to 3 are omitted or briefly described for convenience of description.

Referring to FIG. 4, in one or more example embodiments, a plurality of subpixels configured to emit light of a plurality of colors may be disposed in the display area DA of the display panel 110 included in the display device 100. For example, the display area DA of the display panel 110 may include at least one red subpixel SPr configured to emit a light of red color, at least one green subpixel SPg configured to emit a light of green color, and at least one blue subpixel SPb configured to emit a light of blue color. Each subpixel SP can be configured to emit a light of corresponding color depending on a type of light emitting element ED formed in a respective light emitting area EA, and a bank 340 having openings for defining each light emitting area EA may be formed around each light emitting area EA.

FIG. 4 illustrates an example where a liquid composition droplet DPs is provided by an inkjet process on an upper surface of the bank 340. It may be desired that the liquid composition droplet DP is provided at an equal interval so that the liquid composition droplet DP can be corresponded to each subpixel SP. However, liquid composition droplets DP may not be provided at an equal intervals due to an error in the manufacturing process. In this situation, a defect may occur in which openings of the bank 340 in subpixels SP located far away from the liquid composition droplets DP are not completely filled. Further, even when the liquid composition droplets DP are provided at an equal interval, a defect may occur in which some openings of the bank 340 are not completely filled due to an error in the manufacturing process. To address this issue, it may be desired to provide a structure of enabling the liquid composition droplets DF to flow smoothly into openings of the bank 340.

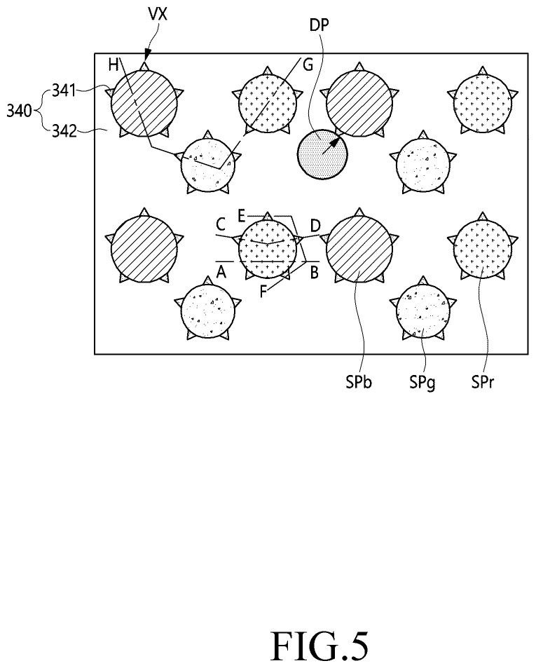

FIG. 5 is another plan view showing an area of the display panel 110 according to embodiments of the present disclosure. In discussions that follow for the configuration of FIG. 5, discussions for features and examples equal, substantially equal, or similar to the features and examples described with reference to FIGS. 1 to 4 are omitted or briefly described for convenience of description.

Referring to FIG. 5, the bank 340 may include one or more openings each having one or more vertexes VX. For example, the bank 340 may include two or more openings at least partially overlap with each other, at least one of two or more openings having one or more vertexes VX. A first bank 341 may be exposed between an opening of the bank 340 with one or more vertexes VX and a light emitting area of a subpixel SP. A liquid composition droplet DP may be provided on an upper surface of the bank 340, for example, on an upper surface of a second bank 342, by an inkjet process. When the liquid composition droplet DP comes into contact with the one or more vertexes of the bank 340, the liquid composition droplet DP may easily move to the opening of the bank 340 by capillary pressure, and thereafter, the opening of the bank 340 may be completely filled with the liquid composition droplet DP.

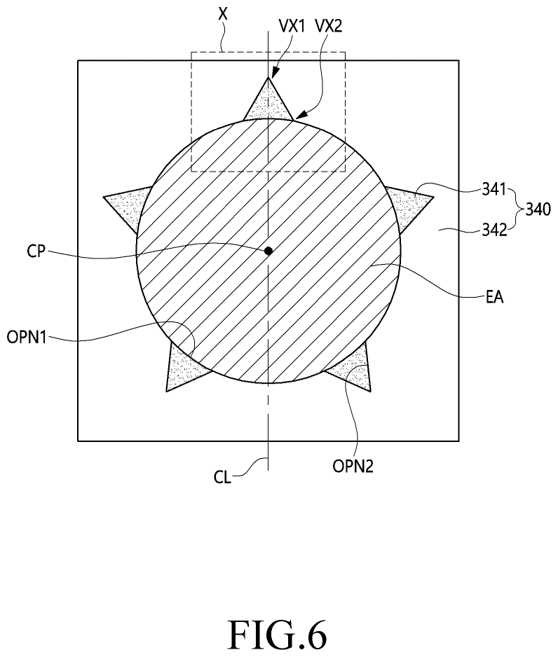

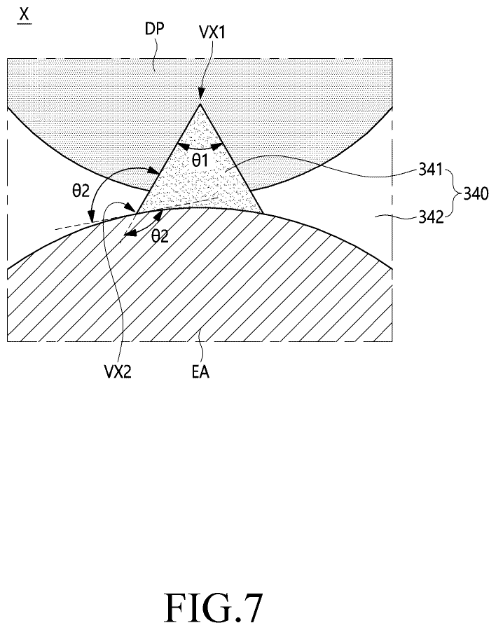

FIG. 6 is an example enlarged plan view illustrating an opening (including OPN1 and OPN2) of the bank 340 in the display panel 110 according to embodiments of the present disclosure. FIG. 7 is an example enlarged plan view of area X in FIG. 6. In discussions that follow for the configuration of FIG. 6, discussions for features and examples equal, substantially equal, or similar to the features and examples described with reference to FIGS. 1 to 5 are omitted or briefly described for convenience of description.

FIG. 6 illustrates an enlarged plan view of an opening (including OPN1 and OPN2) of the bank 340 in the display panel 110 according to embodiments of the present disclosure. Each opening may include a first opening OPN1 formed in a first bank 341 and at least one second opening OPN2 formed in a second bank 342.

It should be noted here that although discussions for the illustration of FIG. 6 are provided based a blue subpixel SPb and openings corresponding thereto, but the discussions that follow may be applied to equally, substantially equally, subpixels (SPr and/or SPg) of other colors and openings corresponding thereto. In FIG. 6, the first opening OPN1 may be a portion, or a portion of an inclined surface, of the first bank 341, and the second opening OPN2 may be a portion, or a portion of an inclined surface, of the second bank 342.

As illustrated in FIG. 6, the opening (including OPN1 and OPN2) may have an area greater than a corresponding light emitting area EA, and the light emitting area EA may be disposed inside of the opening (including OPN1 and OPN2).

The opening (including OPN1 and OPN2) may include first vertices VX1 and second vertices VX2 that are distinct from each other in a plan view. Although FIG. 6 illustrates the opening (including OPN1 and OPN2) having a shape including five first vertices VX1 and ten second vertices VX2, however, embodiments of the present disclosure are not limited thereto. Each of the first vertices VX1 may have an interior angle of 90° or less. Each of the second vertices VX2 may have an interior angle of more than 90° and less than or equal to 270°.

Each of the first vertices VX1 may be located farther away from the center CP of the opening (including OPN1 and OPN2) than at least one second vertex VX2 adjacent to the first vertices VX1 among the second vertices VX2. This is to cause liquid composition provided on an upper surface of the first encapsulation layer 351 to easily flow into the inside of the opening area (including OPN1 and OPN2) when forming the second encapsulation layer 352 illustrated in FIG. 3.

In one or more embodiments, the display device can cause liquid composition droplets DP to flow into the inside of each opening (including OPN1 and OPN2) by the configuration of the opening including the first vertices VX1.

The center CP of the opening (including OPN1 and OPN2) may be the center of gravity of the shape of the opening (including OPN1 and OPN2). The center CP of the opening (including OPN1 and OPN2) may be the intersection of diagonals of a polygon defined by the opening area (including OPN1 and OPN2). For example, the center CP of the opening (including OPN1 and OPN2) may be the same as the center of the light emitting area EA of a blue subpixel SPb.

As illustrated in FIGS. 6 and 7, the first vertices VX1 and the second vertices VX2 may be different from vertices in mathematics. For example, each opening (including OPN1 and OPN2) may be formed by removing a portion of the bank 340 by a photolithography process and an etching process, and due to limitations on the process precision, the first vertices VX1 and the second vertices VX2 may be formed in a curved shape instead of a straight shape.

Thus, a straight line may be formed between each first vertex VX1 and each second vertex VX2, and a curve may be formed between second vertices VX2.

Referring to FIGS. 6 and 7, the spreading force of the liquid composition droplet DP provided on the upper surface of the bank 340 may be determined by the capillary pressure. The greater the capillary pressure, the better the liquid composition droplet DP can spread into the opening (including OPN1 and OPN2). According to these configurations, the liquid composition can be more easily filled in the opening (including OPN1 and OPN2).

The capillary pressure Pc is defined by Equation 1 as follows.

$${P}_{c} = {P}_{( non - wetting phase )} - {P}_{( wetting phase )} ∝ γ ( \frac{1}{{R}_{x}} + \frac{1}{{R}_{y}} ) \qquad [ Equation 1 ]$$

Here, γ is the surface tension, Rx is the interfacial curvature radius in the plane direction, and Ry is the interfacial curvature radius in the thickness direction.

As illustrated in FIG. 7, when the first vertex VX1 has an acute internal angle Θ1, the curvature radius of the first vertex VX1 can be relatively small. Accordingly, the capillary pressure Pc of the liquid composition droplet DP adjacent to the first vertex VX1 can increase.

As the internal angle Θ1 of the first vertex VX1 is reduced, the capillary pressure Pc can increase. A square or rectangle has an internal angle of 90°, and an internal angle Θ1 of a regular polygon can increase as the number of sides increases. This shape can relatively reduce the capillary pressure Pc.

As illustrated in FIG. 6, an opening (including OPN1 and OPN2) having a different shape from a circular light emitting area EA may be formed to form an opening (including OPN1 and OPN2) having an internal angle (Θ1) of 90° or less. Referring to FIGS. 6 and 7, each of the second vertices VX2 may have an internal angle Θ2 more than 90°. The internal angle Θ2 may be less than or equal to 270°.

In one or more embodiments, since an opening (including OPN1 and OPN2) corresponding to a light emitting region EA has one or more first vertices VX1, the display device can provide an advantage of increasing the probability of causing a liquid composition droplet DP to flow into the opening (including OPN1 and OPN2). Since the first vertices VX1 are symmetrically arranged around the light emitting region EA, even when the liquid composition droplet DF moves upwardly, downwardly, leftwardly, and/or rightwardly more than an intended value, and then drips, the display device can provide an advantage of increasing the probability of causing the liquid composition droplet DP to flow into the opening (including OPN1 and OPN2). Each of the second vertices VX2 may be disposed between two adjacent first vertices among the first vertices VX1.

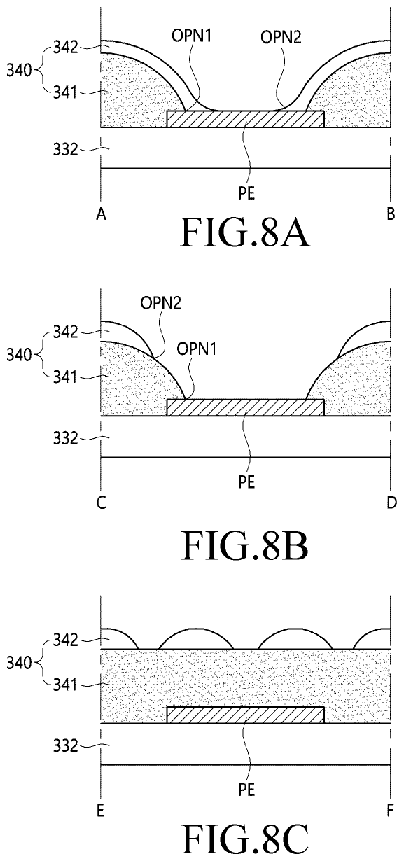

FIGS. 8A, 8B, and 8C are example cross-sectional views taken along lines A-B, C-D, and E-F of FIG. 5 in the display panel 110 according to embodiments of the present disclosure. In discussions that follow for the configuration of FIGS. 8A, 8B, and 8C, discussions for features and examples equal, substantially equal, or similar to the features and examples described with reference to FIGS. 1 to 7 are omitted or briefly described for convenience of description.

Referring to FIGS. 8A, 8B, and 8C, in one or more example embodiments, each of subpixels SP included in the display device 110 may have the bank 340 with a slightly different cross-sectional shape depending on locations, or one or more, of subpixels SP included in the display device 110 may have a cross-sectional shape of the bank 340 slightly different from those of the remaining one or more subpixels SP depending on locations. For example, the cross-sections cut along lines A-B, C-D may be cross-sections of an opening (including OPN1 and OPN2) of the bank 340, and the cross-section cut along line E-F may be a cross-section of an edge of the opening (including OPN1 and OPN2) of the bank 340.

For example, in the display panel 110 cut along line A-B of FIG. 5 that corresponds to a location of a subpixel that is between the vertices VX1 and VX2 as shown in FIG. 8A, the bank 340 may include a first bank 341 and a second bank 342 formed on the first bank 341. The first bank 341 may be disposed on a corresponding pixel electrode PE such that a portion of the pixel electrode PE is exposed and form a first opening OPN1 as shown in FIG. 8A. The second bank 342 may be disposed on the pixel electrode PE such that a portion of the pixel electrode PE is exposed and form a second opening OPN2 as shown in FIG. 8A. As shown in FIG. 8A, an end of the second bank 342 is in contact with the pixel electrode PE.

In addition, in the display panel 110 cut along line C-D of FIG. 5 as shown in FIG. 8B that is a location of the subpixel that corresponds to vertices VX1, the bank 340 may include the first bank 341 and the second bank 342 disposed on the first bank 341. The first bank 341 may be disposed on the pixel electrode PE such that a portion of the pixel electrode PE is exposed and form the first opening OPN1 as shown in FIG. 8B. The second bank 342 may be disposed on the first bank 341 to be spaced apart from the pixel electrode PE and form a second opening OPN2 as shown in FIG. 8B. Thus, at the location that corresponds to vertices VX1, the second bank 342 is on the first bank 341 but does not contact the pixel electrode PE.

In addition, in the display panel 110 cut along line E-F of FIG. 5 as shown in FIG. 8C, the bank 340 may include the first bank 341 and the second bank 342 disposed on the first bank 341 in an edge of the opening (including OPN1 and OPN2) of the bank 340. The second bank 342 disposed on the first bank 341 may include at least one second opening OPN2 to expose a portion of the upper surface of the first bank 341 as shown in FIG. 8C. The first open area OPN1 and the second open area OPN2 may have different sizes and/or shapes.

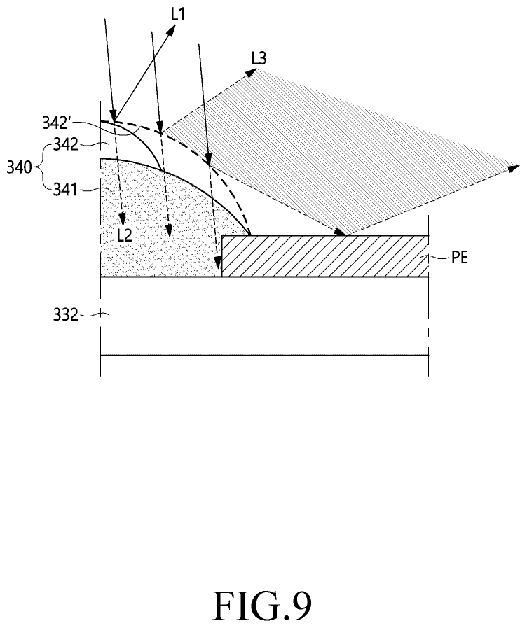

FIG. 9 illustrates a reflection path of external light in the bank 340 of display panel 110 according to embodiments of the present disclosure. In discussions that follow for the configuration of FIG. 9, discussions for features and examples equal, substantially equal, or similar to the features and examples described with reference to FIGS. 1 to 8 are omitted or briefly described for convenience of description.

Referring to FIG. 9, some light L1 of external light reaching the bank 340 may be reflected from at least one second bank (342 and/or 342′), which is a transparent bank. Some light L2 of the external light reaching the bank 340 may be absorbed by the first bank 341, which is a black bank. Some light L3 of the external light reaching the bank 340 may be reflected from the at least one second bank (342 and/or 342′), which is the transparent bank, and may be diffracted and travel inside of a corresponding subpixel SP. For example, since the bank 340 has a structure where the first bank 341, which is the black bank, and the second bank 342, which is the transparent bank, are differently disposed in each subpixel SP, constructive interference and destructive interference can be reduced, and thereby, mura defects can be reduced or eliminated.

For example, each of subpixels SP included in the display device 110 may have the bank 340 with a slightly different cross-sectional shape depending on locations, or one or more, of subpixels SP included in the display device 110 may have a cross-sectional shape of the bank 340 slightly different from those of the remaining one or more subpixels SP depending on locations. For example, a cross-sectional the first bank, which is the black bank, of each of subpixels SP included in the display device 110 may have different shapes and/or sizes, and/or a cross-sectional the second bank, which is the transparent bank, of each of subpixels SP included in the display device 110 may have different shape and/or size; for example, a cross-sectional the first bank, which is the black bank, of one or more of subpixels SP included in the display device 110 and a cross-sectional the first bank, which is the black bank, of the remaining one or more subpixels SP may have different shapes and/or sizes, and/or a cross-sectional the second bank, which is the transparent bank, of one or more of subpixels SP included in the display device 110 and a cross-sectional the second bank, which is the transparent bank, of the remaining one or more subpixels SP may have different shapes and/or sizes. However, the present disclosure is not limited thereto.

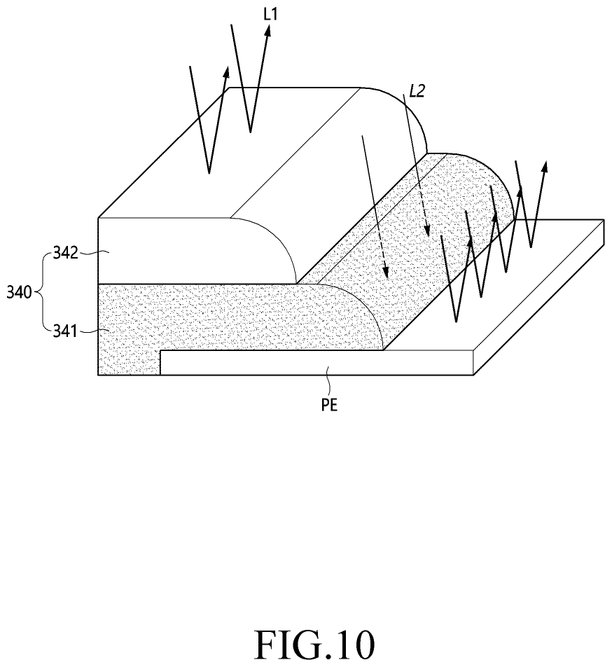

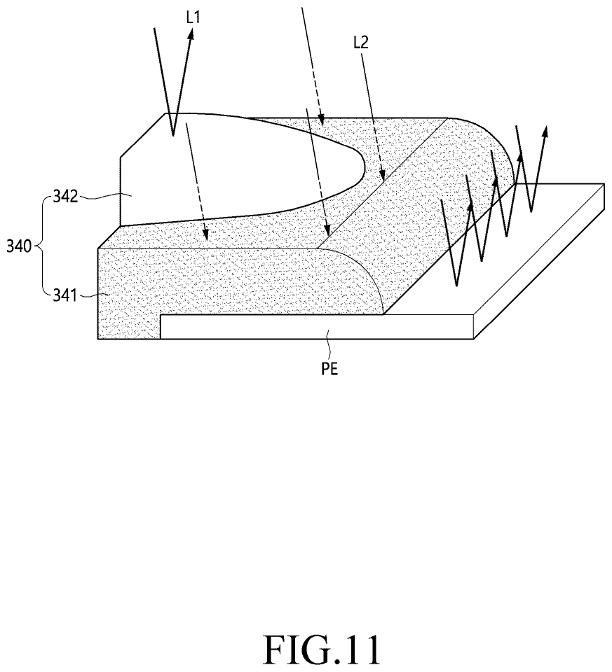

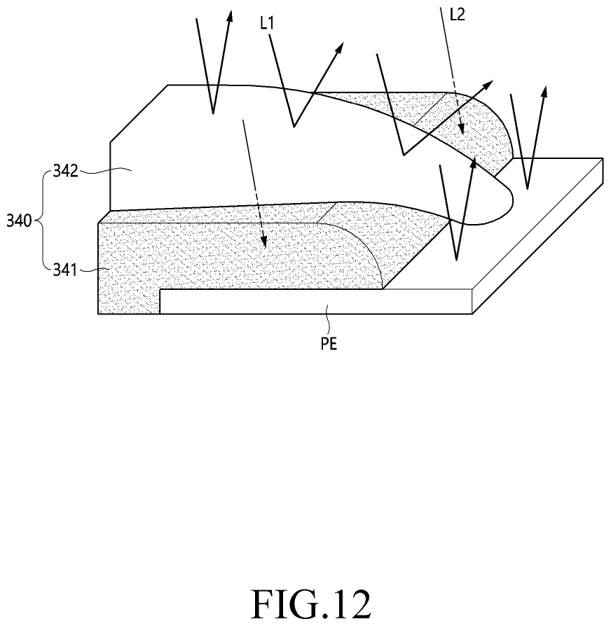

FIG. 10, FIG. 11 and FIG. 12 illustrate example reflection paths of external light in the bank 340 of display panel 110 according to embodiments of the present disclosure. In discussions that follow for the configuration of FIGS. 10 to 12, discussions for features and examples equal, substantially equal, or similar to the features and examples described with reference to FIGS. 1 to 10 are omitted or briefly described for convenience of description.

Referring to FIG. 10, some light L1 of external light reaching the bank 340 may be reflected to the outside from a second bank 342, which is a transparent bank. Some light L2 of the external light reaching the bank 340 may be absorbed by a first bank 341, which is a black bank.

Referring to FIG. 11, some light L1 of external light reaching the bank 340 may be reflected to the outside from a second bank 342, which is a transparent bank. Some light L2 of the external light reaching the bank 340 may be absorbed by a first bank 341, which is a black bank. It should be noted that as the second bank 342 forms a pattern on the first bank 341, an exposed area of the first bank 341 may increase, and therefore, the absorption of the external light by the first bank 341 may increase.

Referring to FIG. 12, some light L1 of external light reaching the bank 340 may be reflected to the outside from a second bank 342, which is a transparent bank. Some light L2 of the external light reaching the bank 340 may be absorbed by a first bank 341, which is a black bank. The second bank 342 may be disposed to extend to a corresponding pixel electrode PE, and in this structure, an incident angle and a reflection angle of external light by the second bank 342 may be changed. For example, the light L1 reflected from the second bank 342 may be diffracted and travel inside of a corresponding subpixel SP. According to these configurations, since the bank 340 has a structure where the first bank 341, which is the black bank, and the second bank 342, which is the transparent bank, are differently disposed in each subpixel SP, constructive interference and destructive interference can be reduced, and thereby, mura defects can be reduced or eliminated.

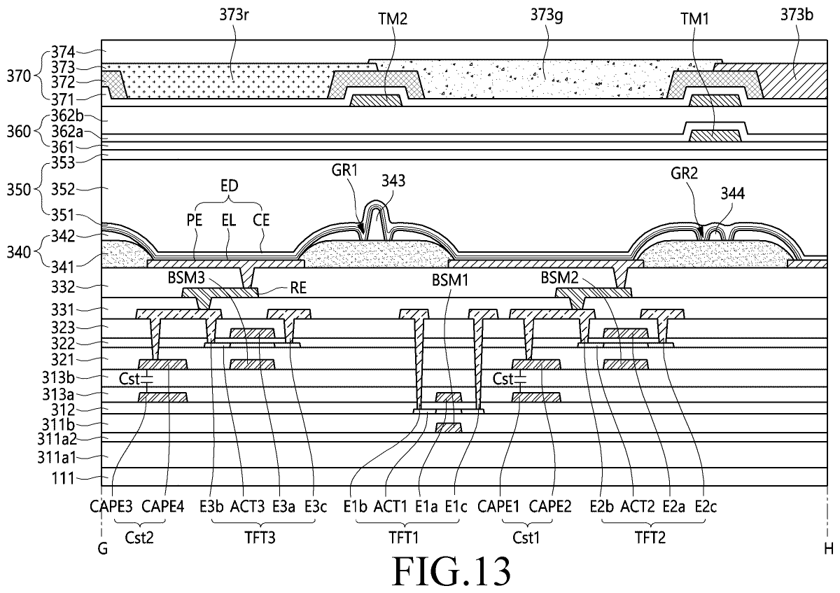

FIG. 13 is an example cross-sectional view taken along line G-H of FIG. 2 in the display panel 110 according to embodiments of the present disclosure. In discussions that follow for the configuration of FIG. 13, discussions for features and examples equal, substantially equal, or similar to the features and examples described with reference to FIGS. 1 to 12 are omitted or briefly described for convenience of description.

Referring to FIG. 13, in one or more example embodiments, the display panel 110 may include a substrate 111, a first buffer layer 311, a first gate insulating layer 312, a first interlayer insulating layer 313, a second buffer layer 321, a second gate insulating layer 322, a second interlayer insulating layer 323, a planarization layer 320, thin film transistors (TFT1, TFT2, TFT3), capacitors (Cst1, Cst2), a light emitting element ED, a bank 340, an encapsulation layer 350, a touch sensor layer 360, and a color filter layer 370.

Referring to FIG. 13, the first buffer layer 311 may be disposed on the substrate 111. The first buffer layer 311 may include a lower buffer layer 311a and an upper buffer layer 311b. The lower buffer layer 311a may include two layers (311a1 and 311a2). In these implementations, the two layers (311a1 and 311a2) may include different materials.

A first active layer ACT1 of a first thin film transistor TFT1 may be disposed on the first buffer layer 311. The first active layer ACT1 may include a channel region where a channel is formed, a source connection region on a first side of the channel region, and a drain connection region on an opposing second side of the channel region.

The first gate insulating layer 312 may be disposed on the first active layer ACT1 of the first transistor TFT1. The first gate insulating layer 312 may include at least one of silicone oxide (SiOx), silicone nitride (SiNx), and silicone oxynitride (SiOxNy). For example, the first gate insulating layer 312 may be configured as a single layer or multi-layer of silicone oxide (SiOx), silicone nitride (SiNx), or silicone oxynitride (SiOxNy), for example, the first gate insulating layer 312 may be formed by inorganic film in a single layer or in multiple layers, for example, the inorganic film in a single layer may be a silicone oxide (SiOx) film, a silicone nitride (SiNx) film or a silicone oxynitride (SiOxNy), and inorganic films in multiple layers may formed by alternately stacking at least one of one or more silicone oxide (SiOx) films, one or more silicone nitride (SiNx) films and one or more silicone oxynitride (SiOxNy) films, and one or more amorphous silicon (a-Si), but the example embodiments of the present disclosure are not limited thereto. A first gate electrode E1a of the first thin transistor TFT1 may be disposed on the first gate insulating layer 312. The first interlayer insulating layer 313 may be disposed on the first gate electrode E1a of the first thin film transistor TFT1. The first interlayer insulating layer 313 may include at least one of silicone oxide (SiOx), silicone nitride (SiNx), and silicone oxynitride (SiOxNy). For example, the first interlayer insulating layer 313 may be configured as a single layer or multi-layer of silicone oxide (SiOx), silicone nitride (SiNx), or silicone oxynitride (SiOxNy), for example, the first interlayer insulating layer 313 may be formed by inorganic film in a single layer or in multiple layers, for example, the inorganic film in a single layer may be a silicone oxide (SiOx) film, a silicone nitride (SiNx) film or a silicone oxynitride (SiOxNy), and inorganic films in multiple layers may formed by alternately stacking at least one of one or more silicone oxide (SiOx) films, one or more silicone nitride (SiNx) films and one or more silicone oxynitride (SiOxNy) films, and one or more amorphous silicon (a-Si), but the example embodiments of the present disclosure are not limited thereto. For example, the first interlayer insulating layer 313 may include two layers (313a and 313b). In these implementations, the two layers (313a and 313b) may include different materials.

The second buffer layer 321 may be disposed on the first interlayer insulating layer 313.

A second active layer ACT2 of a second thin film transistor TFT2 may be disposed on the second buffer layer 321. The second active layer ACT2 may include a channel region in which a channel is formed, a source connection region on one side of the channel region, and a drain connection region on the other side of the channel region.

The second gate insulating layer 322 may be disposed on the second active layer ACT2 of the second thin film transistor TFT2. The second gate insulating layer 322 may include at least one of silicone oxide (SiOx), silicone nitride (SiNx), and silicone oxynitride (SiOxNy). For example, the second gate insulating layer 322 may be configured as a single layer or multi-layer of silicone oxide (SiOx), silicone nitride (SiNx), or silicone oxynitride (SiOxNy), for example, the second gate insulating layer 322 may be formed by inorganic film in a single layer or in multiple layers, for example, the inorganic film in a single layer may be a silicone oxide (SiOx) film, a silicone nitride (SiNx) film or a silicone oxynitride (SiOxNy), and inorganic films in multiple layers may formed by alternately stacking at least one of one or more silicone oxide (SiOx) films, one or more silicone nitride (SiNx) films and one or more silicone oxynitride (SiOxNy) films, and one or more amorphous silicon (a-Si), but the example embodiments of the present disclosure are not limited thereto. A second gate electrode E2a of the second thin film transistor TFT2 may be disposed on the second gate insulating layer 322. The second interlayer insulating layer 323 may be disposed on the second gate electrode E2a of the second thin film transistor TFT2. The second interlayer insulating layer 323 may include at least one of silicone oxide (SiOx), silicone nitride (SiNx), and silicone oxynitride (SiOxNy). For example, the second interlayer insulating layer 323 may be configured as a single layer or multi-layer of silicone oxide (SiOx), silicone nitride (SiNx), or silicone oxynitride (SiOxNy), for example, the second interlayer insulating layer 323 may be formed by inorganic film in a single layer or in multiple layers, for example, the inorganic film in a single layer may be a silicone oxide (SiOx) film, a silicone nitride (SiNx) film or a silicone oxynitride (SiOxNy), and inorganic films in multiple layers may formed by alternately stacking at least one of one or more silicone oxide (SiOx) films, one or more silicone nitride (SiNx) films and one or more silicone oxynitride (SiOxNy) films, and one or more amorphous silicon (a-Si), but the example embodiments of the present disclosure are not limited thereto.

A first source electrode E1b and a first drain electrode E1c of the first thin film transistor TFT1 and a second source electrode E2b and a second drain electrode E2c of the second thin film transistor TFT2 may be disposed on the second interlayer insulating layer 323.

The first source electrode E1b and the first drain electrode E1c of the first thin film transistor TFT1 may be connected to the source connection region and the drain connection region of the first active layer ACT1, respectively, through holes of the second interlayer insulating layer 323, the second gate insulating layer 322, the second buffer layer 321, the first interlayer insulating layer 313, and the first gate insulating layer 312.

The second source electrode E2b and the second drain electrode E2c of the second thin film transistor TFT2 may be connected to the source connection region and the drain connection region of the second active layer ACT2, respectively, through holes of the second interlayer insulating layer 323 and the second gate insulating layer 322.

A first storage capacitor Cst1 may be formed by a first capacitor electrode CAPE1 and a second capacitor electrode CAPE2.

The second source electrode E2b of the second transistor TFT2 may be electrically connected to the second capacitor electrode CAPE2 through holes of the second interlayer insulating layer 323, the second gate insulating layer 322, and the second buffer layer 321.

A first shield pattern BSM1 may be disposed between the lower buffer layer 311a and the upper buffer layer 311b. A second shield pattern BSM2 may be disposed between the first interlayer insulating layer 313 and the second buffer layer 321.

A third thin film transistor TFT3, a second storage capacitor Cst2, and a third shield pattern BSM3 may be disposed over the substrate 111. The third thin film transistor TFT3 may include a third active layer ACT3, a third gate electrode E3a, a third source electrode E3b, and a third drain electrode E2c. The second storage capacitor Cst2 may include a third capacitor electrode CAPE3 and a fourth capacitor electrode CAPE4. The third thin film transistor TFT3 may be formed in the same layer and with the same configuration as the second thin film transistor TFT2. The second storage capacitor Cst2 may be formed in the same layer and with the same configuration as the first storage capacitor Cst1. The third shield pattern BSM3 may be formed in the same layer and with the same configuration as the second shield pattern BSM1.

A first planarization layer 331 may be disposed on the thin film transistors (TFT1, TFT2, and TFT3).

A connection electrode RE may be disposed on the first planarization layer 331. The connecting electrode RE may electrically interconnect the second source electrode E2b of the second thin film transistor TFT2 and a pixel electrode PE of a green subpixel SPg. The connecting electrode RE may electrically interconnect the third source electrode E3b of the third thin film transistor TFT3 and a pixel electrode PE of a red subpixel SPr.

A second planarization layer 332 may be disposed on the connecting electrode RE. For example, each of the first planarization layer 331 and the second planarization layer 332 can be formed of an organic layer such as an acryl-based material, an epoxy-based material, a phenolic-based material, a polyamide-based material, or a polyimide-based material, but example embodiments of the present disclosure are not limited thereto.

The display panel 110 may include the light emitting element ED. The light emitting element ED may be disposed on the second planarization layer 332. The light emitting element ED may include a pixel electrode PE, an intermediate layer EL, and a common electrode CE.

The bank 340 may be disposed to overlap with a portion of an upper surface of the pixel electrode PE. The bank 340 may be disposed to expose a portion of the upper surface of the pixel electrode PE. The bank 340 may include an opening corresponding to the light emitting element ED.

The bank 340 may include a first bank 341 and a second bank 342 on the first bank 341. The first bank 341 may be a black bank. The second bank 342 may be a transparent bank.

In one or more embodiments, grooves (GR1 and GR2) may be disposed in respective portions of a non-light emitting area between subpixels SP. For example, a pair of grooves included in each of the grooves (GR1 and GR2) may be disposed in a portion of the non-light emitting area. The grooves (GR1 and GR2) can serve to block leakage current between adjacent subpixels SP. As the movement of leakage current to adjacent subpixels SP is blocked by the grooves (GR1 and GR2), the unintentional light emitting of the adjacent subpixels SP can be prevented.

A spacer 343 may be disposed in an area between the subpixels SP. For example, the spacer 343 may be disposed between the pair of grooves of a first groove GR1. The spacer 343 may be formed to protrude in a vertical direction from the substrate 111. The spacer 343 may include the same material as the bank 340. For example, the spacer 343 may include the same material as the second bank 342. Therefore, a contact between a mask and the display panel 110 in a subsequent deposition process can be minimized.

In one or more embodiments, a protrusion 344 may be disposed in an area between the subpixels SP. For example, the protrusion 344 may be disposed between the pair of grooves of a second groove GR2. The protrusion 344 may be formed to protrude in the vertical direction from the substrate 111. The protrusion 344 may be formed lower than the spacer 343 in the cross-sectional view.

The intermediate layer EL may be disposed on the upper surface of the pixel electrode PE exposed by the bank 340.

Although FIG. 13 illustrates a structure in which the intermediate layer EL is in the form of a single layer, however, embodiments of the present disclosure are not limited thereto. For example, the intermediate layer EL may include multiple organic layers.

The intermediate layer EL may emit light of at least one color among red R, green G, and blue B. However, embodiments of the present disclosure are not limited thereto.

The common electrode CE of the light emitting element ED may be disposed on the intermediate layer EL.

Although FIG. 13 illustrates a structure in which the common electrode CE is in the form of a single layer, however, embodiments of the present disclosure are not limited thereto. For example, the common electrode CE may be in the form of a multilayer including two or more layers.

The encapsulation layer 350 may be disposed on the common electrode CE.

For example, the encapsulation layer 350 may include a first encapsulation layer 351 disposed on the common electrode CE, a second encapsulation layer 352 disposed on the first encapsulation layer 351, and a third encapsulation layer 353 disposed on the second encapsulation layer 352. The first and third encapsulation layers (351 and 353) may include an inorganic insulating material, and the second encapsulation layer 352 may include an organic insulating material.

The encapsulation layer 350 can prevent moisture and oxygen from penetrating into the light emitting element ED.

The encapsulation layer 350 may include the touch sensor layer 360 in which a touch sensor is formed.

For example, to form a plurality of touch electrodes TE, the touch sensor layer 360 may include a first touch metal layer in which a plurality of first touch metals TM1 are disposed, and a second touch metal layer in which a plurality of second touch metals TM2 are disposed. In this implementation, the touch sensor layer 360 may further include at least one touch interlayer insulating layer (362a and/or 362b) disposed between the first touch metal layer and the second touch metal layer.

The touch sensor layer 360 may further include a touch buffer layer 361 disposed on the encapsulation layer 350. The touch buffer layer 361 may be disposed between the encapsulation layer 350 and the touch metal layer. For example, the first touch metal layer may be disposed on the touch buffer layer 361, and the at least one touch interlayer insulating layer (362a and/or 362b) may be disposed on the first touch metal layer.

The at least one touch interlayer insulating layer (362a and/or 362b) may include a first touch interlayer insulating layer 362a and a second touch interlayer insulating layer 362b. The first touch interlayer insulating layer 362a may include an inorganic insulating material. The second touch interlayer insulating layer 362b may include an organic insulating material. However, embodiments of the present disclosure are not limited thereto.

The touch sensor layer 360 may include capacitive touch sensors that sense touch input based on a change in capacitance before and after the touch input. The touch sensor layer 360 may include metal line patterns and insulating films that form the capacitance of the touch sensors. The insulating films may insulate intersection portions of the metal line patterns and planarize the surface of the touch sensor layer.

A polarizing plate (not shown in the drawing) may be adhered onto the touch sensor layer 360. The polarizing plate may improve the visibility and contrast ratio by converting polarization of external light reflected by the metal patterns of the circuit layer. The polarizing plate may be implemented as a polarizing plate in which a linear polarizing plate and a phase delay film are bonded, or a circular polarizing plate, but not limited thereto.

The color filter layer 370 may be disposed on the touch sensor layer 360.

The color filter layer 370 may include a color filter buffer layer 371, a black matrix 372, a color filter 373, and a protection layer 374.

The black matrix 372 may be disposed on the color filter buffer layer 371. The black matrix 372 may overlap with a non-light emitting area between subpixels SP. The black matrix 372 may be overlapped with the bank 340. The black matrix 372 may be overlapped with the touch metals (TM1 and TM2).

The color filter 373 may be disposed between portions of the black matrix 372. The color filter 373 may include a red color filter 373r corresponding to a red subpixel SPr, a green color filter 373g corresponding to a green subpixel SPg, and a blue color filter 373b corresponding to a blue subpixel SPb.

A protection layer 374 may be disposed on the color filter 373.

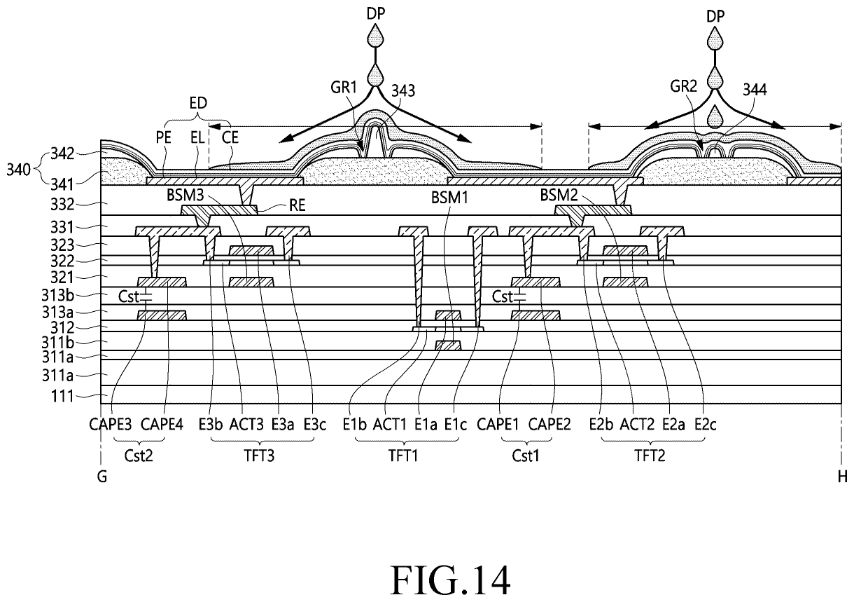

FIG. 14 illustrates an example process of forming an encapsulation layer 350 in the display panel 110 according to embodiments of the present disclosure. In discussions that follow for the configuration of FIG. 14, discussions for features and examples equal, substantially equal, or similar to the features and examples described with reference to FIGS. 1 to 13 are omitted or briefly described for convenience of description.

It should be noted that the cross-sectional structure of FIG. 14 may be the same as the cross-sectional structure illustrated in FIG. 13. Tacking account of the similarity, discussions for the configuration of FIG. 14 are provided by focusing on the process of forming the encapsulation layer 350.

Referring to FIG. 14, in one or more example embodiments, the encapsulation layer 350 may be formed by an inkjet process. For example, a second encapsulation layer 352 including an organic insulating material among layers of the encapsulation layers 350 may be formed by the inkjet process.

Referring to FIG. 14, liquid composition droplets DP for forming the second encapsulation layer 352 on the upper surface of the bank 340 may be provided by the inkjet process. The liquid composition droplets DP may be designed to be provided on the upper surface of the bank 340 between subpixels SP so that the liquid composition droplets DP can flow into openings of the bank 340 and completely fill the openings of the bank 340. For example, the liquid composition droplets DP may be provided at equal intervals corresponding to a spacer 343 and a protrusion 344 disposed on the upper surface of the bank 340. The liquid composition droplets DP falling on the spacer 343 and protrusion 344 can flow into at least one opening of the bank 340 and completely fill the at least one opening of the bank 340. In this configuration, to improve the flowability of the liquid composition droplets DP, the bank 340 may have a double bank structure of a first bank 341 and a second bank 342 on the first bank 341. As discussed above, at least one opening of the bank 340 formed by the first bank 341 and the second bank 342 may have a vertex shape so that liquid composition droplets DP flowing around the opening area of the bank 340 can move inside of the opening of the bank 340 by a higher capillary pressure.

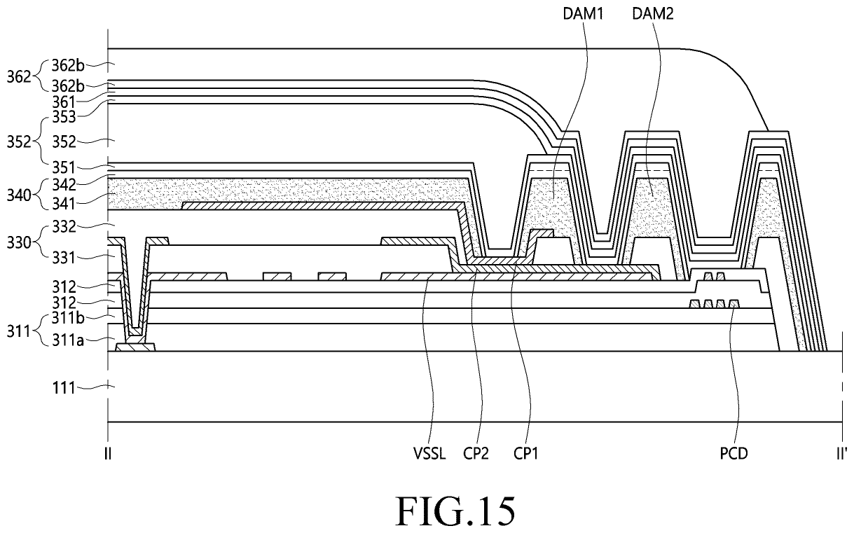

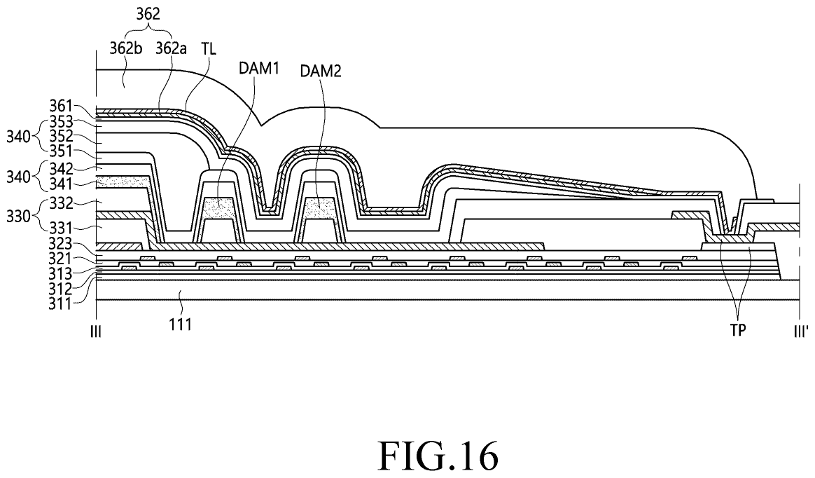

FIGS. 15 and 16 are example cross-sectional views in outer areas of the display panel 110 according to embodiments of the present disclosure. FIG. 15 is an example cross-sectional view taken along line II-II′ of FIG. 2, and FIG. 16 is an example cross-sectional view taken along line III-III′ of FIG. 2. In discussions that follow for the configuration of FIGS. 15 and 16, discussions for features and examples equal, substantially equal, or similar to the features and examples described with reference to FIGS. 1 to 14 are omitted or briefly described for convenience of description.

It should be noted that the configurations of the display panel 110 in FIGS. 15 and 16 may have substantially the same configuration as the insulating layers in the configurations of the display panel 110 in FIGS. 3, 13, and 14. Tacking account of the similarity, discussions for the stack-up structures of FIGS. 15 and 16 are provided by focusing on features different from the stack-up structures of FIGS. 3, 13, and 14.

Referring to FIGS. 15 and 16, in one or more example embodiments, the display panel 110 may include at least one dam (DAM1 and/or DAM2).

The at least one dam (DAM1 and/or DAM2) may be formed by including a planarization layer 330 and a bank 340. For example, the at least one dam (DAM1 and/or DAM2) may have a structure in which a second planarization layer 332, a first bank 341, and a second bank 342 are stacked. In one or more embodiments, the at least one dam (DAM1 and/or DAM2) may be formed by further including a spacer 343 disposed on the second bank 342. A height of the at least one dam (DAM1 and/or DAM2) can be increased as the spacer 343 is further stacked on the at least one dam (DAM1 and/or DAM2). When the height of the at least one dam (DAM1 and/or DAM2) is increased, the second encapsulation layer 352 can be easily prevented from overflowing to the outside.

Referring to FIG. 15, a crack prevention pattern PCD may be formed on the substrate 111. The crack prevention pattern PCD may be disposed in a portion of the non-display area NDA located further outwardly from the display area DA than the at least one base voltage line VSSL, but embodiments of the present disclosure are not limited thereto.

For example, the crack prevention pattern PCD may be a pattern for preventing of lines running on the substrate 111 from being cracked. In one or more embodiments, the crack prevention pattern PCD may be disposed in a zigzag pattern, but embodiments of the present disclosure are not limited thereto.

Referring to FIG. 16, a touch routing line TL may extend along an inclined surface of an encapsulation layer 352, extend over an upper portion of at least one dam (DAM1 and/or DAM2), and reach a touch pad TP. In this configuration, the planarization layer 330 may be disposed discontinuously between the at least one dam (DAM1 and/or DAM2) and the touch pad TP. For example, the planarization layer 330 may not be disposed in an area adjacent to the at least one dam (DAM1 and/or DAM2), and may be disposed again in an area adjacent to the touch pad TP.

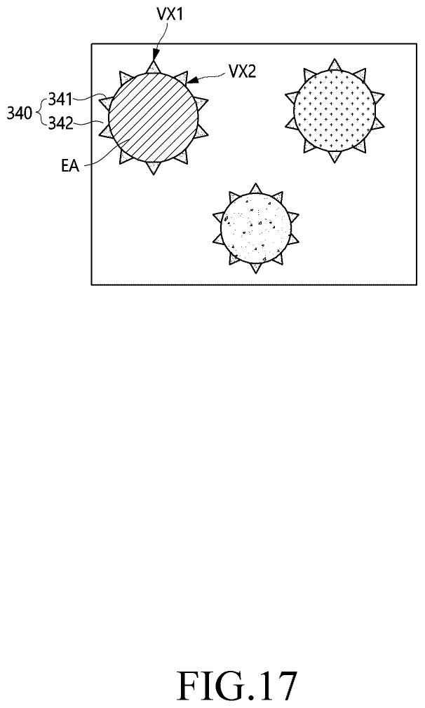

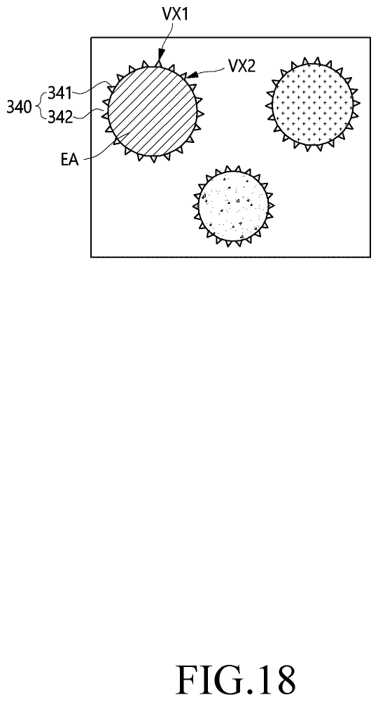

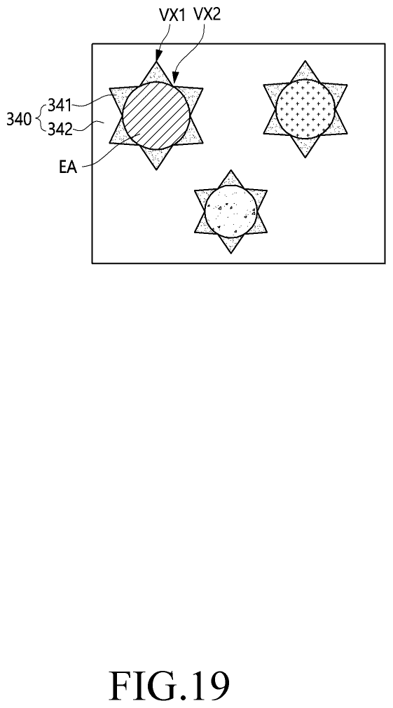

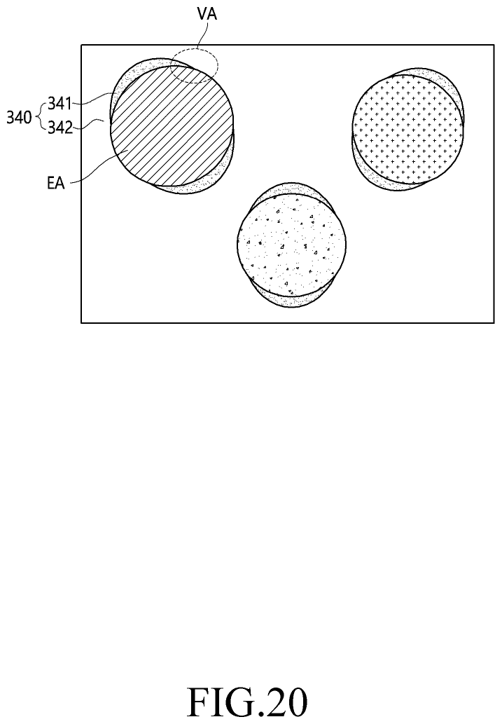

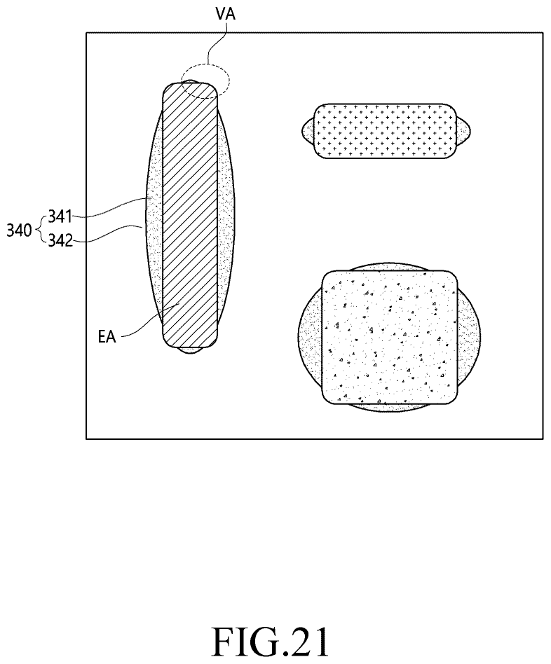

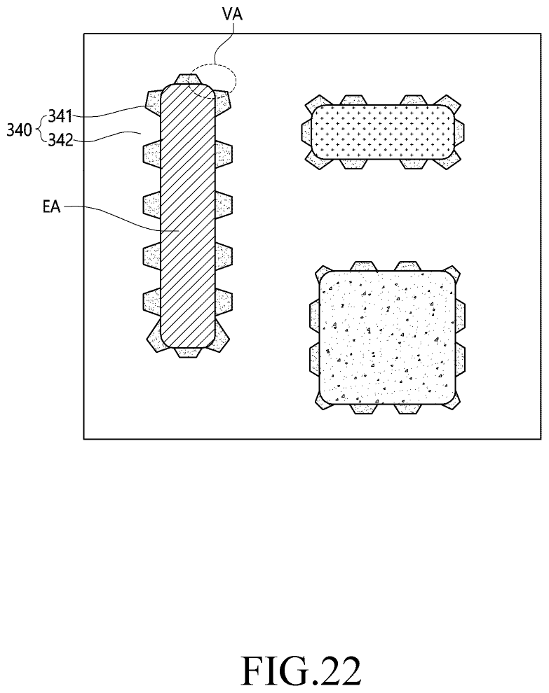

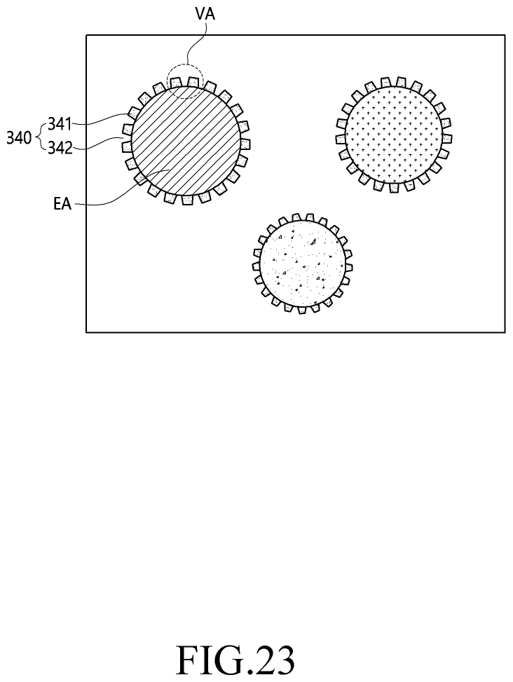

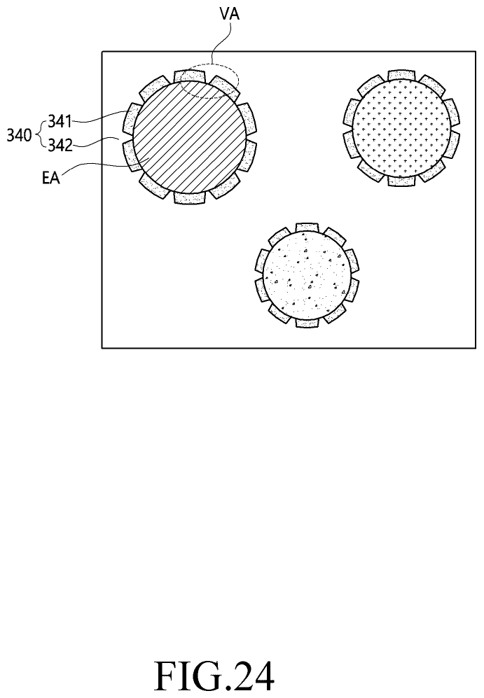

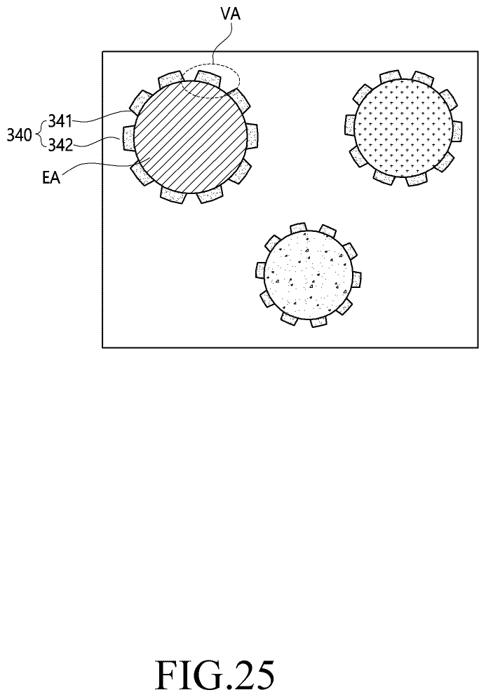

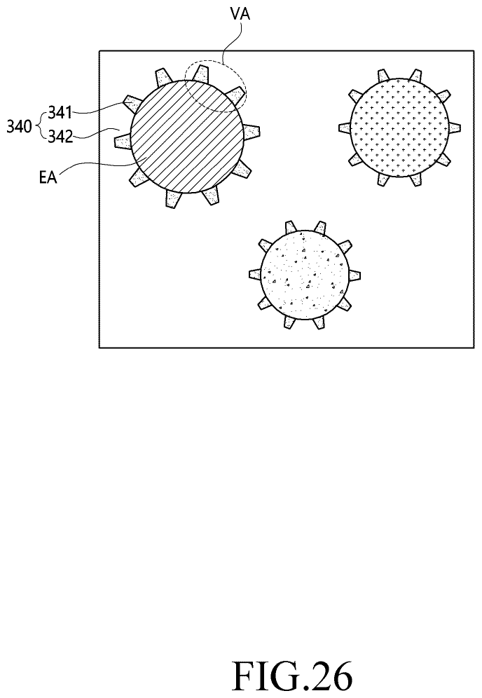

FIG. 17, FIG. 18, FIG. 19, FIG. 20, FIG. 21, FIG. 22, FIG. 23, FIG. 24, FIG. 25 and FIG. 26 illustrate example shapes of openings OPN of the bank 340 in the display panel 110 according to embodiments of the present disclosure. In discussions that follow for the configuration of FIGS. 17 to 26, discussions for features and examples equal, substantially equal, or similar to the features and examples described with reference to FIGS. 1 to 16 are omitted or briefly described for convenience of description.

Referring to FIG. 2, in one or more example embodiments, the display area DA defined in the display panel 110 may include a normal area NA and one or more optical areas OA. In this configuration, a bank 340 disposed in the normal area NA and a bank 340 disposed in the one or more optical areas OA may have various shapes. For example, a shape of the bank 340 disposed in the normal area NA and a shape of the bank 340 disposed in the one or more optical area OA may have the same shape. In one example embodiment, the shape of the bank 340 disposed in the normal area NA and the shape of the bank 340 disposed in the one or more optical area OA may have one shape of shapes of openings OPN of the bank 340 illustrated in FIGS. 17 to 26. In another example, the shape of the bank 340 disposed in the normal area NA and the shape of the bank 340 disposed in the one or more optical area OA may have different shapes. In one example embodiment, the shape of the bank 340 disposed in the normal area NA and the shape of the bank 340 disposed in the one or more optical area OA may have different shapes of shapes of openings OPN of the bank 340 illustrated in FIGS. 17 to 26. The normal area NA may include banks 340 in which light emitting areas EA have a circular shape, and the one or more optical area OA may include banks 340 in which light emitting areas EA have a rectangular shape. The normal area NA may include one or more shape of shapes of openings OPN of the bank 340 illustrated in FIG. 17, FIG. 18, FIG. 19, FIG. 20, FIG. 23, FIG. 24, FIG. 25 and FIG. 26, and the one or more optical area OA may include one or more shape of shapes of openings OPN of the bank 340 illustrated in FIG. 20 and FIG. 21.

Referring to FIGS. 17 and 18, in one or more example embodiments, the display panel 110 may include subpixels SP in which light emitting areas EA have a circular shape and a bank 340 has openings each including a plurality of first vertices VX1 and a plurality of second vertices VX2. For example, the openings of the bank 340 may be configured such that a straight line is formed between adjacent first and second vertices (VX1 and VX2), and a curved line is formed between adjacent second vertices VX2. A tangent line adjacent to each second vertex VX2 may be used to measure an interior angle of the second vertices VX2. The first vertices VX1 can smoothly guide liquid composition droplets DP, which may be provided randomly and irregularly, to flow inside of the openings of the bank 340.

Referring to FIG. 19, in one or more example embodiments, the display panel 110 may include subpixels SP in which light emitting areas EA have a circular shape and a bank 340 has openings each including a plurality of first vertices VX1 and a plurality of second vertices VX2. For example, the openings of the bank 340 may be configured such that a straight line is formed between adjacent first and second vertices (VX1 and VX2). The second vertices VX2 may be disposed to contact a circular shape of the light emitting area EA. The first vertices VX1 can smoothly guide liquid composition droplets DP, which may be provided randomly and irregularly, to flow inside of the openings of the bank 340.

Referring to FIGS. 20 to 26, in one or more example embodiments, the display panel 110 may include subpixels SP in which light emitting areas EA have a rectangular or circular shape and a bank 340 has openings each including an inflection area VA adjacent to a corresponding one of the light emitting areas EA. The inflection area VA may be defined to be adjacent to each vertex. The inflection area VA may be formed by a shape in which an opening adjacent to the light emitting area and located outside of the light emitting area protrudes in an elliptical or square shape. For example, the inflection area VA may have a shape protruding outwardly from the center CP of the opening of the bank 340.

In Equation 1 discussed above, sides of the square or rectangular shape are equivalent to Rx being infinite. The fact that an inflection point or an inflection area is defined may mean that an area where Rx is less than infinity occurs. Therefore, it can be understood that the capillary pressure increases relatively as the inflection area VA increases.

All openings of the bank 340 illustrated in FIGS. 17 to 26 may have a shape with portions symmetrical with respect to a virtual line passing through the center of the openings, as in the opening of the bank 340 illustrated in FIG. 6.

According to the one or more embodiments described herein, a display device may be provided that is capable of improving reflective visibility by including a structure where an opening of a first bank and an opening of a second bank have different shapes.

According to the one or more embodiments described herein, a display device may be provided that is capable of improving the flowability of a material included in an encapsulation layer by including a structure where an opening of a first bank and an opening of a second bank have different shapes.

According to the one or more embodiments described herein, a display device may be provided that is capable of causing a material included in an encapsulation layer to be easily spread into an open area by including a structure where an opening of a first bank and an opening of a second bank have different shapes.

According to the one or more embodiments described herein, a display device may be provided that is capable of enabling process optimization through the application of an inkjet process for forming an encapsulation layer by including a structure where an opening of a first bank and an opening of a second bank have different shapes.

The display device according to one or more example embodiments of the present disclosure may be described as follows.

A display device according to one example embodiment of the present disclosure comprises a display panel including a display area displaying images and including a plurality of subpixels, each of the plurality of subpixels including a light emitting area; and a bank disposed around the light emitting area, wherein the bank includes two or more openings partially overlapping with each other in a direction perpendicular to the display panel, and wherein the two or more openings have different shapes.

According to one example embodiment of the present disclosure, the two or more openings have different shapes in a plan view parallel to the display panel.

According to one example embodiment of the present disclosure, at least one of the two or more openings includes first vertices and second vertices that are distinct from each other, and wherein straight lines are formed between the first vertices and the second vertices adjacent to each other, and curve lines are formed between the second vertices adjacent to each other.

According to one example embodiment of the present disclosure, each of the first vertices is located farther away from a center of the opening than at least one second vertex adjacent to the first vertices among the second vertices.

According to one example embodiment of the present disclosure, at least one of the two or more openings includes an inflection area, the inflection area having a shape protruding outwardly from a center of the opening.

According to one example embodiment of the present disclosure, the bank includes a first bank and a second bank, and the two or more openings includes a first opening disposed in the first bank and a second opening disposed in the second bank.

According to one example embodiment of the present disclosure, the first bank is a black bank, and the second bank is a transparent bank.

According to one example embodiment of the present disclosure, in each of the plurality of subpixels, at least one of the first bank and the second bank is differently provided.

According to one example embodiment of the present disclosure, in each of the plurality of subpixels, the first bank has a different shape and/or size, and/or the second bank has a different shape and/or size.

According to one example embodiment of the present disclosure, a cross-sectional of the first bank in one or more of the plurality of subpixels, and a cross-sectional of the first bank in the remaining one or more subpixels have different shapes and/or sizes, and/or a cross-sectional of the second bank in one or more of the plurality of subpixels, and a cross-sectional of the second bank in the remaining one or more subpixels have different shapes and/or sizes.

According to one example embodiment of the present disclosure, the display area further includes a non-light emitting area between the plurality of subpixels, and grooves are disposed in the non-light emitting area.

According to one example embodiment of the present disclosure, the grooves include a first pair of grooves, and a spacer is disposed between the first pair of grooves.

According to one example embodiment of the present disclosure, the grooves further include a second pair of grooves, and a protrusion is disposed between the second pair of grooves.

According to one example embodiment of the present disclosure, a height of protrusion is less than a height of the spacer.

According to one example embodiment of the present disclosure, the two or more openings have different shapes in a cross-sectional view perpendicular to the display panel.

According to one example embodiment of the present disclosure, the display panel further includes a non-display area provided with lines, and the non-display area includes a crack prevention pattern to prevent the lines from being cracked.

According to one example embodiment of the present disclosure, the crack prevention pattern is a zigzag pattern.

According to one example embodiment of the present disclosure, each of the plurality of subpixels includes a light emitting element forming the light emitting area, the light emitting element including a first electrode, and the bank is disposed on the first electrode, and at least one of the two or more openings of the bank overlaps with a portion of the first electrode.

A display panel according to one example embodiment of the present disclosure comprises a substrate including a display area displaying images and including a plurality of subpixels, each of the plurality of subpixels including a light emitting area; and a bank disposed around the light emitting area, wherein the bank includes two or more openings partially overlapping with each other in a direction perpendicular to the display panel, and wherein the two or more openings have different shapes.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the principles described herein may be applied to other embodiments and applications without departing from the scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display device comprising:
a display panel including a display area displaying images and including a plurality of subpixels, each of the plurality of subpixels including a light emitting area; and
a bank disposed around the light emitting area,
wherein the bank includes two or more openings partially overlapping with each other in a direction perpendicular to the display panel, and
wherein the two or more openings have different shapes.

2. The display device according to claim 1, wherein the two or more openings have different shapes in a plan view parallel to the display panel.

3. The display device according to claim 2, wherein at least one of the two or more openings includes first vertices and second vertices that are distinct from each other, and
wherein straight lines are formed between the first vertices and the second vertices adjacent to each other, and curve lines are formed between the second vertices adjacent to each other.

4. The display device according to claim 3, wherein each of the first vertices is located farther away from a center of the opening than at least one second vertex adjacent to the first vertices among the second vertices.

5. The display device according to claim 2, wherein at least one of the two or more openings includes an inflection area, the inflection area having a shape protruding outwardly from a center of the opening.

6. The display device according to claim 1, wherein the bank includes a first bank and a second bank, and wherein the two or more openings includes a first opening disposed in the first bank and a second opening disposed in the second bank.

7. The display device according to claim 6, wherein the first bank is a black bank, and the second bank is a transparent bank.

8. The display device according to claim 7, wherein in each of the plurality of subpixels, at least one of the first bank and the second bank is differently provided.

9. The display device according to claim 8, wherein in each of the plurality of subpixels, the first bank has a different shape and/or size, and/or the second bank has a different shape and/or size.

10. The display device according to claim 8, wherein a cross-sectional of the first bank in one or more of the plurality of subpixels, and a cross-sectional of the first bank in the remaining one or more subpixels have different shapes and/or sizes, and/or
wherein a cross-sectional of the second bank in one or more of the plurality of subpixels, and a cross-sectional of the second bank in the remaining one or more subpixels have different shapes and/or sizes.

11. The display device according to claim 1, wherein the display area further includes a non-light emitting area between the plurality of subpixels, and at least one of grooves is disposed on the bank in the non-light emitting area.

12. The display device according to claim 1, wherein at least one spacer is disposed on the bank in a first subpixel.

13. The display device according to claim 12, wherein at least one protrusion is disposed on the bank in a second subpixel adjacent to the first subpixel.

14. The display device according to claim 13, wherein a height of protrusion is less than a height of the spacer.

15. The display device according to claim 1, wherein the bank includes a first bank and a second bank, the first bank and the second bank having different shapes or sizes in a cross-sectional view perpendicular to the display panel.

16. The display device according to claim 1, further comprising a dam in a non-display area of the display panel,
wherein a crack prevention pattern is disposed at the outside of the dam in a direction away from the display area.

17. The display device according to claim 1, wherein each of the plurality of subpixels includes a first transistor and a second transistor disposed on different layers.

18. The display device according to claim 17, wherein a material in an active layer of the first transistor and a material in an active layer of the second transistor are different.

19. The display device according to claim 1, wherein the display area includes a normal area and one or more optical areas, and wherein a subpixel disposed in the normal area and a subpixel disposed in the one or more optical area have different sizes.

20. A display panel comprising:
a substrate including a display area displaying images and including a plurality of subpixels, each of the plurality of subpixels including a light emitting area; and
a bank disposed around the light emitting area,
wherein the bank includes two or more openings partially overlapping with each other in a direction perpendicular to the display panel, and
wherein the two or more openings have different shapes.
